(19) United States
(12) Patent Application Publication
(10) Pub. No.: US 2019/0212854 A1
(43) Pub. Date: Jul. 11, 2019

(54) SUBSTRATE, DISPLAY DEVICE AND METHOD OF PRODUCING SUBSTRATE

(71) Applicant: Sharp Kabushiki Kaisha, Sakai City (JP)

(72) Inventor: Mikihiro NOMA, Sakai City (JP)

(21) Appl. No.: 16/242,055

(22) Filed: Jan. 8, 2019

(30) Foreign Application Priority Data
Jan. 11, 2018 (JP) 2018-002568

(51) Int. Cl. G06F 3/041; G06F 3/044; H05K 1/02

(52) U.S. Cl. CPC G06F 3/0412; G06F 2203/04103; H05K 1/0298; G06F 3/044

(57) ABSTRACT

A first in-print layer having a first conductive layer formation groove formed by partially recessing its surface and a first conductive layer formed inside the first conductive layer formation groove are installed, and a first regulating portion, which is disposed to contact an end portion of the first in-print layer to regulate the formation range of the first in-print layer, is also installed.

### CROSS REFERENCE TO RELATED APPLICATION

This application claims priority from Japanese Patent Application No. 2018-002568 filed on Jan. 11, 2018. The entire contents of the priority application are incorporated herein by reference.

### TECHNICAL FIELD

The technology described herein relates to a substrate, a display device and a method of producing the substrate.

### BACKGROUND

In recent years, with respect to an electronic apparatus, such as a tablet type notebook personal computer, a portable type information terminal or the like, in order to improve operability and usability, installation of a touch panel (touch screen) has been carried out. As one example of the method of producing the touch panel, a method described in the following JP Patent No. 5833260 B has been known. The method of producing a touch screen described in JP Patent No. 5833260 B includes a step of preparing a substrate including a first surface and a second surface on the opposite side to the first surface, a step of applying gel to the first surface so as to cure the gel thereon so that a first matrix layer is formed, thereby determining a first groove on the side separated from the substrate of the first matrix layer, a step of filling a conductive material into the first groove, a step of applying gel on the side separated from the substrate of the first matrix layer so as to be cured thereon so that a second matrix layer is formed, thereby determining a second groove on the second matrix layer, and the other step of filling a conductive material into the second groove so that a second conductive layer is formed.

### SUMMARY

In the method of producing the touch screen described in the above-mentioned JP Patent No. 5833260 B, the first matrix layer and the second matrix layer which are respectively formed by curing gel are stacked, and a first groove and a second groove are formed on the first matrix layer and the second matrix layer by using a so-called in-print technique and a first conductive layer and a second conductive layer are formed in the respective grooves. However, in the case when by applying gel onto the surface of the first matrix layer, the second matrix layer is formed, since the gel is applied and spread thereon, a problem arises in which it becomes difficult to precisely control the formation range of the second matrix layer. For this reason, in the case when one portion of the first conductive layer formed inside the first groove on the first matrix layer is utilized as a terminal for use in connecting to an external connection portion, in an attempt to avoid the portion to be formed into the terminal of the first conductive layer from being covered with the second matrix layer, the corresponding portion needs to be disposed out of the assumed largest formation range of the second matrix layer, and for this reason, the frame edge width of the touch screen might become too large.

The technology described herein was made in view of the above circumstances. An object is to make the frame edge narrower.

A substrate of the present invention is provided with an in-print layer having a conductive layer formation groove formed by partially recessing the surface, a conductive layer formed inside of the conductive layer formation groove, and a regulating portion that is disposed so as to be made in contact with the end portion of the in-print layer, to regulate the formation range of the in-print layer.

In this manner, on the surface of the in-print layer, the partially recessed conductive layer formation groove is formed and a conductive layer is formed inside the conductive layer formation groove. At the time of forming the in-print layer, since the formation range of the in-print layer is regulated by the regulating portion that is disposed so as to be made in contact with the end portion of the in-print layer, it becomes possible to prevent the in-print layer from being formed in an excessively expanded state. Therefore, different from the conventional configuration in which so as to make a portion forming the terminal of the first conductive layer avoided from being covered with the second matrix layer, the frame edge width of the touch screen becomes larger, it is possible to desirably make the frame edge width narrower consequently to desirably provide a narrow frame edge.

The method of producing the substrate of the present invention is provided with an in-print layer forming step of forming an in-print layer, a groove forming step of forming a conductive layer formation groove by partially recessing the surface of the in-print layer, a conductive layer forming step of forming a conductive layer inside the conductive layer formation groove, and a regulating portion forming step, which is carried out prior to the in-print layer forming step, of forming a regulating portion so as to be made in contact with the end portion of the in-print layer.

In this manner, when the in-print layer forming step and the groove forming step have been carried out, the partially recessed conductive layer formation groove is formed on the surface of the in-print layer. When the conductive layer forming step is carried out, a conductive layer is formed inside the conductive layer formation groove of the in-print layer. In the regulating portion forming step to be carried out prior to the formation of the in-print layer in the in-print layer forming step, since the regulating portion to be disposed so as to be made in contact with the end portion of the in-print layer is formed, the formation range of the in-print layer is regulated by the regulating portion, upon forming the in-print layer in the in-print layer forming step, so that it becomes possible to prevent the in-print layer from being formed in an excessively expanded state. Therefore, different from the conventional configuration in which so as to make a portion forming the terminal of the first conductive layer avoided from being covered with the second matrix layer, the frame edge width of the touch screen becomes larger, it is possible to desirably make the frame edge width narrower consequently to desirably provide a narrow frame edge.

In accordance with the present invention, it becomes possible to make the frame edge narrower.

### BRIEF DESCRIPTION OF THE DRAWINGS

FIG. 1 is a plan view illustrating an organic EL display device.

FIG. 2 is a schematic cross-sectional view in the vicinity of end portions of an organic EL display panel, a touch panel and a polarizing plate.

FIG. 3 is a plan view illustrating the organic EL panel and the touch panel, which schematically shows a touch panel pattern.

FIG. 4 is a plan view illustrating a second touch electrode in an enlarged manner, which constitutes the touch panel pattern.

FIG. 5 is a plan view illustrating a state in which a first regulating portion is formed on the organic EL panel in a first regulating portion forming step included in the method of producing the touch panel.

FIG. 6 is a cross-sectional view taken along line A-A of FIG. 5.

FIG. 7 is a cross-sectional view taken along line B-B of FIG. 5.

FIG. 8 is a cross-sectional view taken along line A-A of FIG. 5 illustrating a state in which a material for the first in-print layer is supplied onto the organic EL panel in a first in-print layer forming step included in the method of producing the touch panel.

FIG. 9 is a cross-sectional view taken along line B-B of FIG. 5 illustrating a state in which the material for the first in-print layer is supplied onto the organic EL panel in a first in-print layer forming step included in the method of producing the touch panel.

FIGS. 10A and 10B are views illustrating a first groove forming step included in the method of producing the touch panel.

FIGS. 11A and 11B are views illustrating a first groove forming step included in the method of producing the touch panel.

FIGS. 12A and 12B are views illustrating a first wiring forming step included in the method of producing the touch panel.

FIG. 13 is a plan view illustrating a state in which a second regulating portion is formed on the first in-print layer by a second regulating portion forming step included in the method of producing the touch panel.

FIG. 14 is a cross-sectional view taken along line A-A of FIG. 13.

FIG. 15 is a cross-sectional view taken along line B-B of FIG. 13.

FIG. 16 is a cross-sectional view taken along line A-A of FIG. 13 illustrating a state in which a material for the second in-print layer is supplied onto the first in-print layer in the second in-print layer forming step included in the method of producing the touch panel.

FIG. 17 is a cross-sectional view taken along line B-B of FIG. 13 illustrating a state in which a material for the second in-print layer is supplied onto the first in-print layer in the second in-print layer forming step included in the method of producing the touch panel.

FIGS. 18A and 18B are views illustrating a second groove forming step included in the method of producing the touch panel.

FIGS. 19A and 19B are views illustrating a second groove forming step included in the method of producing the touch panel.

FIGS. 20A and 20B are views illustrating a second wiring forming step included in the method of producing the touch panel.

FIG. 21 is a plan view illustrating a state in which a first regulating portion is formed on the organic EL panel in a first regulating portion forming step included in the method of producing the touch panel.

FIG. 22 is a plan view illustrating a state in which a second regulating portion is formed on the first in-print layer in a second regulating portion forming step included in the method of producing the touch panel.

FIG. 23 is a plan view illustrating an organic EL panel and a touch panel.

FIG. 24 is a partially cut-out perspective view illustrating a ground wiring.

FIG. 25 is a partially cut-out perspective view illustrating a state in which a conductive paste material is applied in a manner so as to straddle between a first ground wiring and a second ground wiring constituting the ground wiring.

FIG. 26 is a plan view illustrating an organic EL display device relating to another embodiment (16).

### DETAILED DESCRIPTION

### First Embodiment

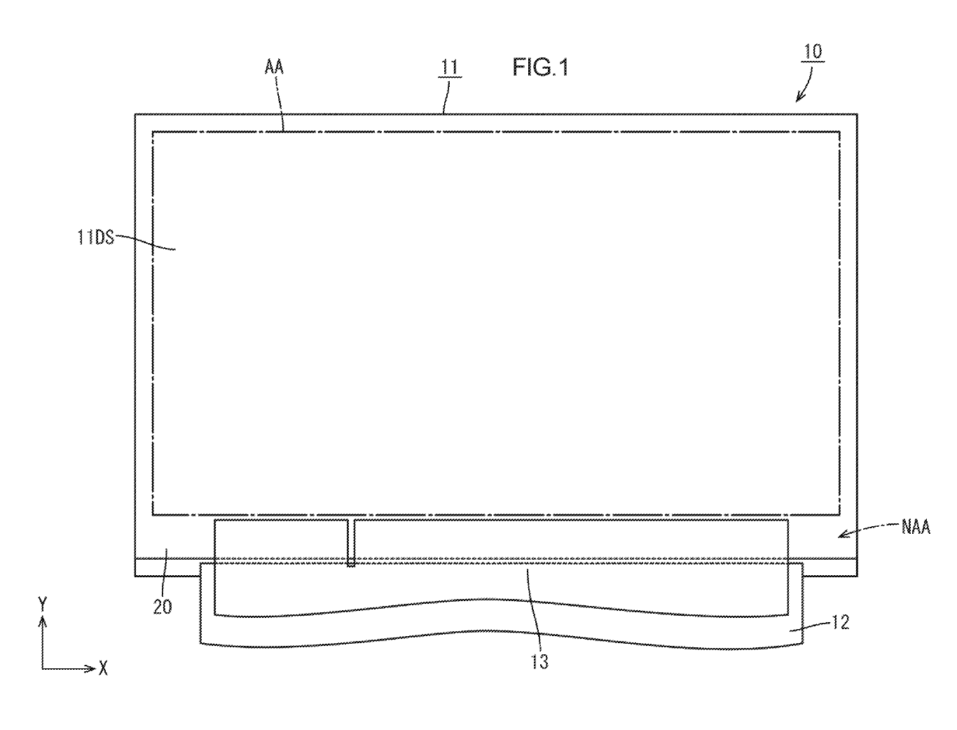

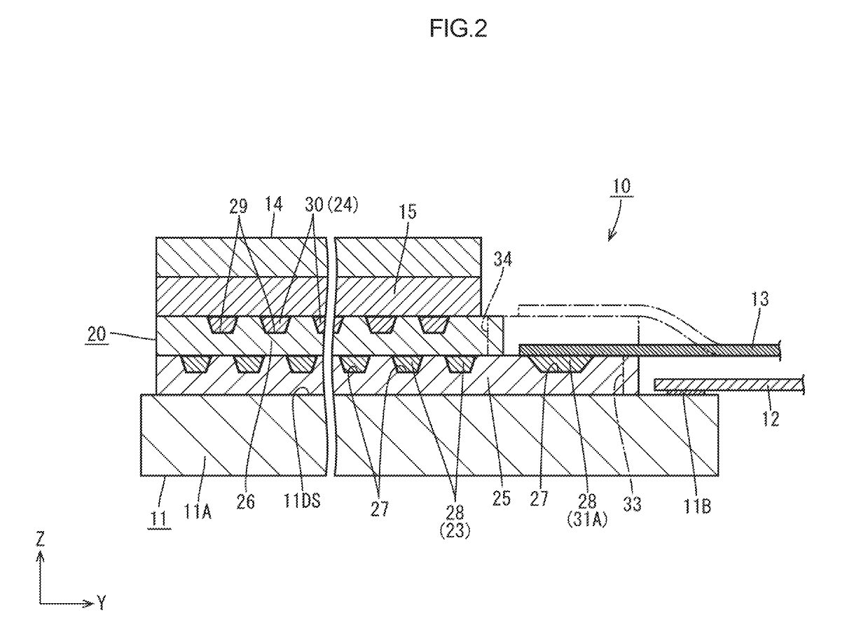

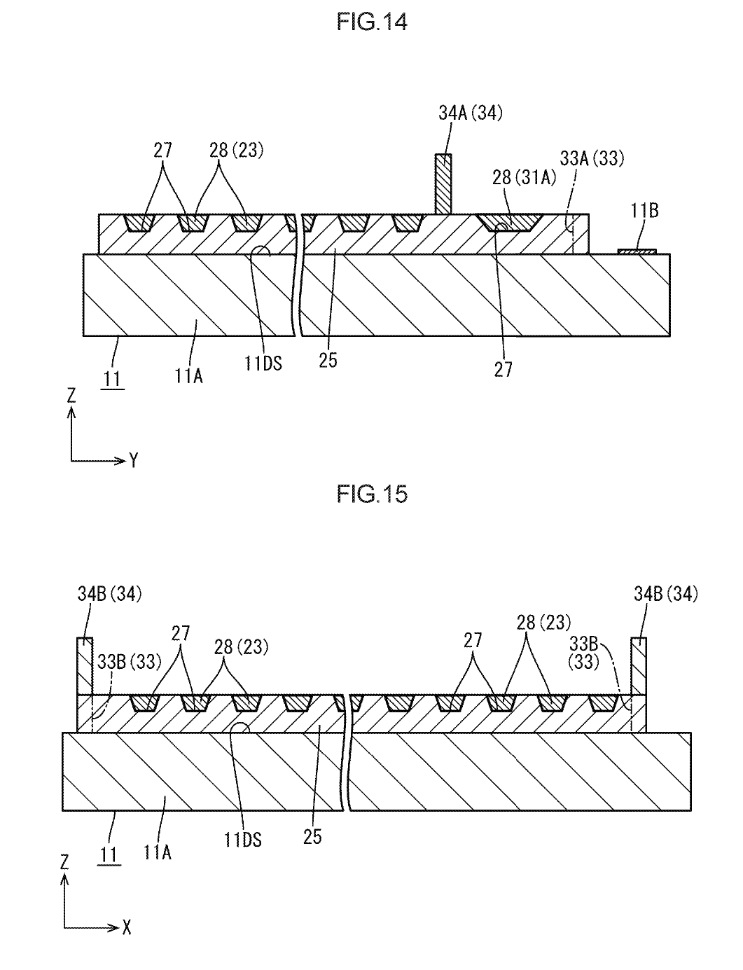

A first embodiment will be described with reference to FIGS. 1 to 20. In the present embodiment, explanation will be given to a method of producing a touch panel (substrate, wiring substrate, position input device) 20 relating to an organic EL display device (display device) 10 with a touch panel function. Additionally, X-axis, Y-axis and Z-axis are indicated on one portion of each of the drawings, and the respective axis directions are illustrated so as to correspond to directions shown in the respective drawings. Moreover, with respect to the longitudinal directions, based upon FIG. 2 and FIGS. 6 to 12, as well as based upon FIGS. 14 to 20, and the upper side of the same drawing is defined as the surface side and the lower side of the same drawing is defined as the rear side.

First, explanation will be given to a configuration of the organic EL display device 10. As shown in FIG. 1 and FIG. 2, the organic EL display device 10 has a laterally extended rectangular shape as a whole, the long side direction is coincident with the X-direction, the short side direction is coincident with the Y-direction and the plate width direction (normal direction of plate surface) is coincident with the Z-direction respectively. The organic EL display device 10 is provided with at least an organic EL panel (display panel, OLED display panel) 11 provided with a display surface 11DS capable of displaying an image on a panel surface on the surface side, a display-use flexible substrate (display panel connection portion) 12 connected to the organic EL panel 11 and a touch panel 20 that is disposed on the display surface 11DS side of the organic EL panel 11 so as to detect a position (input position) at which a user input is made, a touch panel-use flexible substrate (connection portion) 13 to be connected to the touch panel 20, and a polarizing plate 14 disposed on the side opposite to the organic EL panel 11 side relative to the touch panel 20. The organic EL panel 11, the polarizing plate 14 and the touch panel 20 also have the laterally extended rectangular shapes. Among these, the polarizing plate 14 is provided with a polarizing layer (polarizer) that selectively transmits linearly polarizing light in a specific oscillating direction, and is disposed so as to sandwich the touch panel 20 relative to the organic EL panel 11. Moreover, the polarizing plate 14 is provided with a phase difference layer (λ/4 circularly polarizing plate) 15 on the plate surface on the touch panel 20 side. The phase difference layer 15 is formed by applying a liquid crystalline polymer material onto the plate surface on the touch panel 20 side of the polarizing plate 14 so that the phase difference of λ/4 is applied to the transmitting light. By the phase difference layer 15, a reflected light suppressing function or the like for selectively absorbing reflected light can be obtained. Moreover, the polarizing plate 14 including the phase difference layer 15 has its width set to, for example, about 60 μm.

As shown in FIG. 1, the display surface 11DS of the organic EL panel 11 is separated into a display area (active area) AA on which an image is displayed and a non-display area (non-active area) NAA that forms a frame edge shape (frame shape) surrounding the display area AA, and displays no image. Additionally, in FIG. 1, the external shape of the display area AA is indicated by a one dot chain line, and an area outside from the one dot chain line corresponds to the non-display area NAA. As shown in FIG. 2, the organic EL panel 11 is provided with a base member 11A made of a substantially transparent synthetic resin (for example, made of PET) having flexibility. On the base material 11A, constituent members, such as an organic EL layer that emits light, a reflection electrode that reflects light, a TFT (switching element) that is connected to the organic EL layer so as to control an electric current, a fluorescent layer forming the organic EL layer, a moisture absorbing layer (moisture preventive layer) made of a multi-layer film, a sealing member or the like, are formed by using a conventionally known method, such as a vapor deposition method or the like. The semiconductor film installed in the TFT is made of polycrystal silicon or an oxide semiconductor. The base member 11A has its thickness set to, for example, about 40 μm. Moreover, the dimension made by subtracting the thickness of the base member 11A from the thickness of the organic EL panel 11 is set to, for example, about 10 μm. Moreover, the surface on the surface side of the organic EL panel 11 constitutes the display surface 11DS.

As shown in FIG. 1 and FIG. 2, the display-use flexible substrate 12 and the touch panel-use flexible substrate 13 are respectively provided with film-shaped base members made of synthetic resin materials (for example, polyimide based resins or the like) so as to provide flexibility, and a large number of wiring patterns (not shown) are formed on the substrate. The display-use flexible substrate 12 has its one end connected to the base member 11A forming the organic EL panel 11, and also has its other end connected to a control substrate (not shown) serving as a signal supply source so that a signal or the like relating to image display supplied from the control substrate can be transmitted to the base member 11A. On the other hand, the touch panel-use flexible substrate 13 has its one end connected to the touch panel 20, and also has its other end connected to the control substrate (not shown) so that a signal or the like relating to positional detection, supplied from the control substrate can be transmitted to the touch panel 20. To an end portion on one of the longer side (lower side shown in FIG. 1) side on the organic EL panel 11, a panel terminal 11B to be connected to the end portion of the display-use flexible substrate 12 is installed. To an end portion of one of the longer side on the touch panel 20, terminals 31A and 32A to be connected to the end portion of the touch panel-use flexible substrate 13 are installed. Additionally, with respect to the terminals 31A and 32A, detailed explanation will be given later.

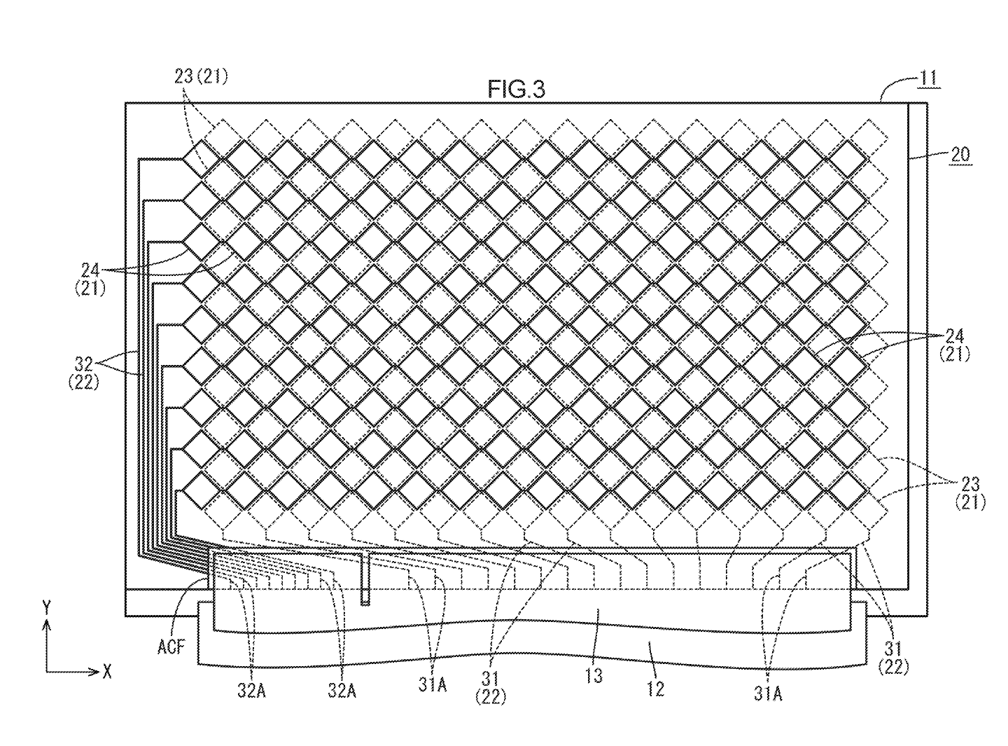

As described earlier, the organic EL panel 11 relating to the present embodiment compatibly has a display function for displaying an image and a touch panel function (positional input function) for detecting a position (input position) at which a user input is made based upon an image to be displayed, and of these functions, the touch panel 20 provided with a touch panel pattern for executing the touch panel function is integrally installed (ON-Cell structure). As shown in FIG. 2, the touch panel 20 is installed in an overlapped manner on the surface side of the organic EL panel 11. The touch panel 20 has its thickness made thinner than that of the base member 11A of the organic EL panel 11 and that of the polarizing plate 14 so as to be set to, for example, about 20 μm. Moreover, when a dimension made by subtracting the thickness of the base member 11A from the thickness of the organic EL panel 11 is added to a thickness of the touch panel 20, the resulting added dimension is, for example, set to about 30 μm. Therefore, since the organic EL display device 10 has its entire thickness made extremely thinner and for example, set to 130 μm, it is superior in flexibility and is desirably used as a device having a foldable usability. The touch panel pattern prepared in the touch panel 20 has a so-called projection type electrostatic capacitance system, and its detection system is set to a mutual capacitance system. As shown in FIG. 3, the touch panel pattern is provided with at least a plurality of touch electrodes (position detection electrodes) 21 that are disposed so as to be aligned into a matrix shape within the in-plane of the touch panel 20. The touch electrodes 21 are disposed in an area to be overlapped with the display area AA of the organic EL panel 11 within the touch panel 20. Therefore, the display area AA in the organic EL panel 11 is substantially coincident with the touch area from which an input position is detectable so that the non-display area NAA is substantially coincident with the non-touch area from which no input position can be detected. Moreover, in the non-touch area of the touch panel 20, a peripheral wiring 22 that has its one end connected to the touch electrode 21 and also has its other end connected to terminals 31A and 32A connected to the touch panel-use flexible substrate 13 is disposed. Moreover, when a user puts his or her finger, serving as a conductor (position input body), not shown, closer to the touch panel 20 in an attempt to input a position based upon an image in the display area AA to be visually recognized by the user, an electrostatic capacitance is formed between the finger and the touch electrode 21. Thus, the electrostatic capacitance to be detected by the touch electrode 21 located close to the finger has a change as the finger comes closer thereto, to become different from the touch electrode 21 located far from the finger so that based upon this, the input position can be detected.

More specifically, as shown in FIG. 3, the touch electrode 21 includes a plurality of first touch electrodes (first position detection electrodes) 23 that are linearly aligned in the Y-axis direction (first direction) and a plurality of second touch electrodes (second position detection electrodes) 24 that are linearly aligned in the X-axis direction (second direction) that is orthogonal (intersect with) to the Y-axis direction. The first touch electrodes 23 and the second touch electrodes 24, each of which has a substantially rhombic shape in its plane shape, are disposed so as to fill in the plane of the touch area within the plate surface of the touch panel 20, that is, in a shape that is mutually non-overlapped state. Moreover, the first touch electrode 23 and the second touch electrode 24 have, for example, about 5 mm in their diagonal dimensions. Adjacent first touch electrodes 23 in the Y-axis direction have their mutually adjacent end portions connected with each other so that the plural first touch electrodes 23 aligned in the Y-axis direction forming a row are electrically connected to one another to form a group of the first touch electrodes 23 in a row state along the Y-axis direction, and by the group of the first touch electrodes 23, an input position in the Y-axis direction can be detected. In the touch area of the touch panel 20, the plural groups of the first touch electrodes 23 are disposed so as to be aligned in the X-axis direction with a predetermined interval. Adjacent second touch electrodes 24 in the X-axis direction have their mutually adjacent end portions connected to each other so that the plural second touch electrodes 24 aligned in the X-axis direction forming a row are electrically connected to one another to form a group of the second touch electrodes 24 in a row state along the X-axis direction, and by the group of the second touch electrodes 24, an input position in the X-axis direction can be detected. In the touch area of the touch panel 20, the plural groups of the second touch electrodes 24 are disposed in parallel with one another in the Y-axis direction with a predetermined interval. As described above, an input position in the X-direction as well as in the Y-direction can be specified.

The connection portions between the mutual first touch electrodes 23 in the above-mentioned group of the first touch electrodes 23 and the connection portions between the mutual second touch electrodes 24 in the group of the second touch electrodes 24 are disposed so as to be overlapped (to intersect with) with each other; however, since they are disposed on mutually different layers so that mutual insulating state (short-circuit prevention) can be maintained. More specifically, as shown in FIG. 2, the touch panel 20 is formed by stacking a first insulating in-print layer (in-print layer) 25 on which the first touch electrodes 23 are formed and a second insulating in-print layer (second in-print layer) 26 on which the second touch electrodes 24 are formed, with the first in-print layer 25 being relatively on the rear side, that is, on the organic EL panel 11 side, with the second in-print layer 26 being relatively on the surface side, that is, on the polarizing plate 14 side. Both of the first in-print layer 25 and the second in-print layer 26 are made of an ultraviolet ray curable resin material (curable material, photocurable material), and have their thicknesses respectively set to, for example, about 10 μm. The first in-print layer 25 and the second in-print layer 26 are stacked on most portion of the organic EL panel 11 except for one portion (formation portion of the panel terminal 11B or the like) corresponding to an installation target of the touch panel 20 in a solidly expanded state. That is, the first in-print layer 25 and the second in-print layer 26 are disposed in a non-overlapped state with the panel terminals 11B. On the first in-print layer 25, a first conductive layer formation groove (conductive layer formation groove, wiring formation groove) 27 formed by partially recessing the surface on the surface side (side opposite to the organic EL panel 11 side) and a first conductive layer (conductive layer, wiring layer) 28 that is disposed inside the first conductive layer formation groove 27 so as to form the first touch electrode 23 or the like are formed. In the same manner, on the second in-print layer 26, a second conductive layer formation groove (second conductive layer, second wiring) 29 formed by partially recessing the surface on the surface side (side opposite to the first in-print layer 25 side) and a second conductive layer (second conductive layer, second wiring) 30 that is disposed inside the second conductive layer formation groove 29 so as to constitute the second touch electrode 24 or the like are installed. The first conductive layer formation groove 27 and the second conductive layer formation groove 29 are formed on the surfaces of the first in-print layer 25 and the second in-print layer 26 by using a so-called in-print method. The first conductive layer formation groove 27 and the second conductive layer formation groove 29 have their groove depths set to about half or less of the thicknesses of the first in-print layer 25 and the second in-print layer 26, that is, more specifically to, for example, less than 5 μm. The first conductive layer 28 and the second conductive layer 30 are formed by drying and curing metal ink (for example, silver nano-ink or the like) containing a metal material (for example, silver or the like) superior in conductivity as a main material. Additionally, the outer surfaces of the first conductive layer 28 and the second conductive layer 30 formed inside the first conductive layer formation groove 27 and the second conductive layer formation groove 29 are preferably made to be flushed with the outermost surfaces of the first in-print layer 25 and the second in-print layer 26 so as to ensure the flatness; however, the present invention is not necessarily limited by this.

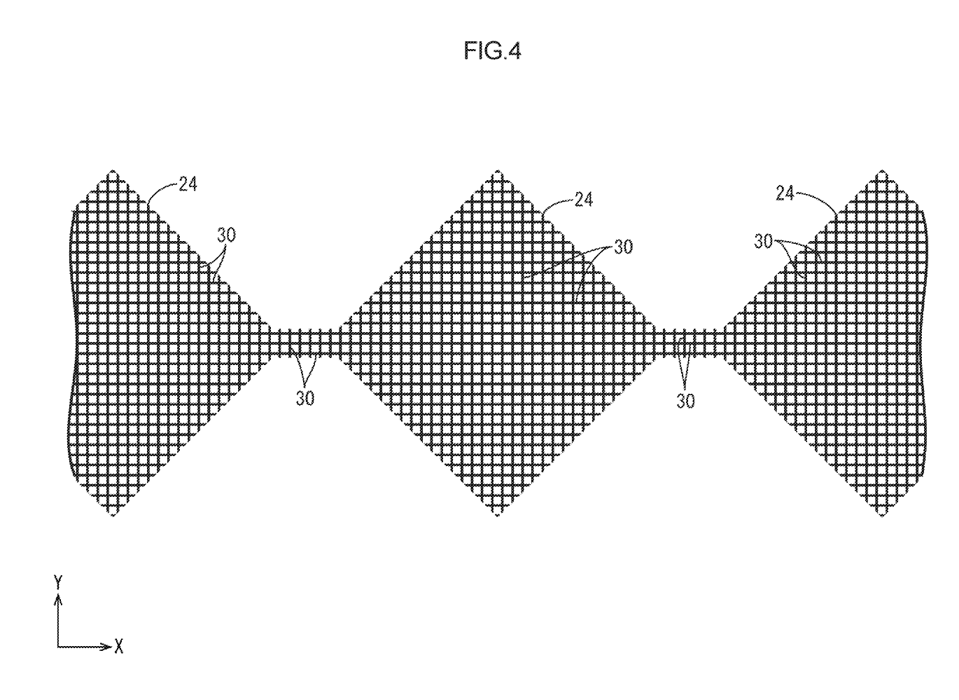

As shown in FIG. 4, the first conductive layer 28 and the second conductive layer 30 have their respective line widths set to be extremely smaller than the outer dimensions (about 5 mm) of the first touch electrode 23 and the second touch electrode 24, that is, to be, for example, about 3 μm, and include those linearly extended in the X-axis direction and those linearly extended in the Y-axis direction. Additionally, in FIG. 4, the second touch electrodes 24 made of the second conductive layer 30 are illustrated as a typical example; however, the first touch electrodes 23 made of the first conductive layer 28 have the same configuration. A large number of the first conductive layers 28 and the second conductive layers 30 that are linearly extended along the X-axis direction are disposed in parallel with one another with an interval relative to the Y-axis direction, while a large number of the first conductive layers 28 and second conductive layers 30 are linearly extended along the Y-axis direction are disposed in parallel with one another with an interval relative to the X-axis direction; thus, the group of the first conductive layers 28 and the group of the second conductive layers 30 are arranged in a network state (mesh state) within the formation areas of the first touch electrodes 23 and the second touch electrodes 24. Moreover, the first conductive layers 28 that are mutually intersected with one another are electrically short-circuited, and the second conductive layers 30 that are mutually intersected with one another are electrically short-circuited. In this manner, in the touch area of the touch panel 20, the first touch electrodes 23 and the second touch electrodes 24 are made to easily transmit light so that with this arrangement, an image inside the display area AA on the organic EL panel 11 is allowed to obtain sufficient display luminescence. In this manner, although the first conductive layers 28 and the second conductive layers 30 have minute structures, since the formation ranges of the first conductive layers 28 and the second conductive layers 30 are preliminarily partitioned by the first conductive layer formation groove 27 and the second conductive layer formation groove 29, the minute first conductive layers 28 and second conductive layers 30 can be disposed at appropriate positions within the in-plane of the touch panel 20. Additionally, the first conductive layer formation groove 27 and the second conductive layer formation groove 29 in which the first conductive layers 28 and the second conductive layers 30 are respectively disposed include a large number of those linearly extend along the X-axis direction and a large number of those linearly extend along the Y-axis direction in the same manner as in the first conductive layers 28 and the second conductive layers 30 so as to form a lattice pattern, with those layers that intersect with each other being communicated with each other.

As shown in FIG. 3, the peripheral wiring 22 is constituted by a first peripheral wiring (peripheral conductive layer) 31 that is disposed in the non-touch area of the first in-print layer 25 and constituted by the first conductive layer 28 and a second peripheral wiring (second peripheral conductive layer) 32 that is disposed in the non-touch area of the second in-print layer 26 and constituted by the second conductive layer 30. The first peripheral wiring 31 is routed from the end portion on the lower side of the group of the first touch electrodes 23, shown in FIG. 3, that extend along the Y-axis direction into a fan shape toward to the assembled area of the touch panel-use flexible substrate 13. The second peripheral wiring 32 is routed from the end portion on the left side of the group of the second touch electrodes 24, shown in FIG. 3, that extend along the X-axis direction toward to the assembled area of the touch panel-use flexible substrate 13. The first peripheral wiring 31 and the second peripheral wiring 32 are respectively provided with a first terminal (terminal) 31A and a second terminal (second terminal) 32A that are disposed in the assembling area of the touch panel-use flexible substrate 13 and electrically connected to the end portion on the touch panel-use flexible substrate 13 side through an anisotropic conductive film ACF. A plurality of the first terminals 31A are disposed on most of the portion on the right side shown in FIG. 3 of the assembling area of the touch panel-use flexible substrate 13 in the X-axis direction in parallel with one another with an interval set therebetween. A plurality of the second terminals 32A are disposed on one portion on the left side (routed-out side of the second peripheral wiring 32 relative to the second touch electrode 24 group), shown in FIG. 3, of assembling area of the touch panel-use flexible substrate 13 in the X-axis direction in parallel with one another with an interval set therebetween. Although the second in-print layer 26 is disposed in an overlapped manner relative to the most of the portions of the first in-print layer 25, it is selectively disposed in a non-overlapped manner relative to the first terminal 31A. These first peripheral wiring 31 and second peripheral wiring 32 are disposed in a non-touch area of the touch panel 20, that is, the non-display area NAA of the organic EL panel 11. Therefore, of the first conductive layer 28 and the second conductive layer 30 (first conductive layer formation groove 27 and second conductive layer formation groove 29), portions that are formed into the first peripheral wiring 31 and the second peripheral wiring 32 are not necessarily formed into a network pattern like portions constituting the first touch electrode 23 and the second touch electrode 24, and may be formed with the same width as that of, for example, the first peripheral wiring 31 and the second peripheral wiring 32.

Moreover, the second touch electrode 24 and the second peripheral wiring 32 disposed on the uppermost surface on the surface side of the touch panel 20 have their most of portions (portions except for the second terminal 32A) covered with the polarizing plate 14 that is affixed onto the surface side of the touch panel 20 as shown in FIG. 2. By this polarizing plate 14, the second touch electrode 24 and the second peripheral wiring 32 are prevented from being exposed to the outside so that the second touch electrode 24 and the second peripheral wiring 32 are protected.

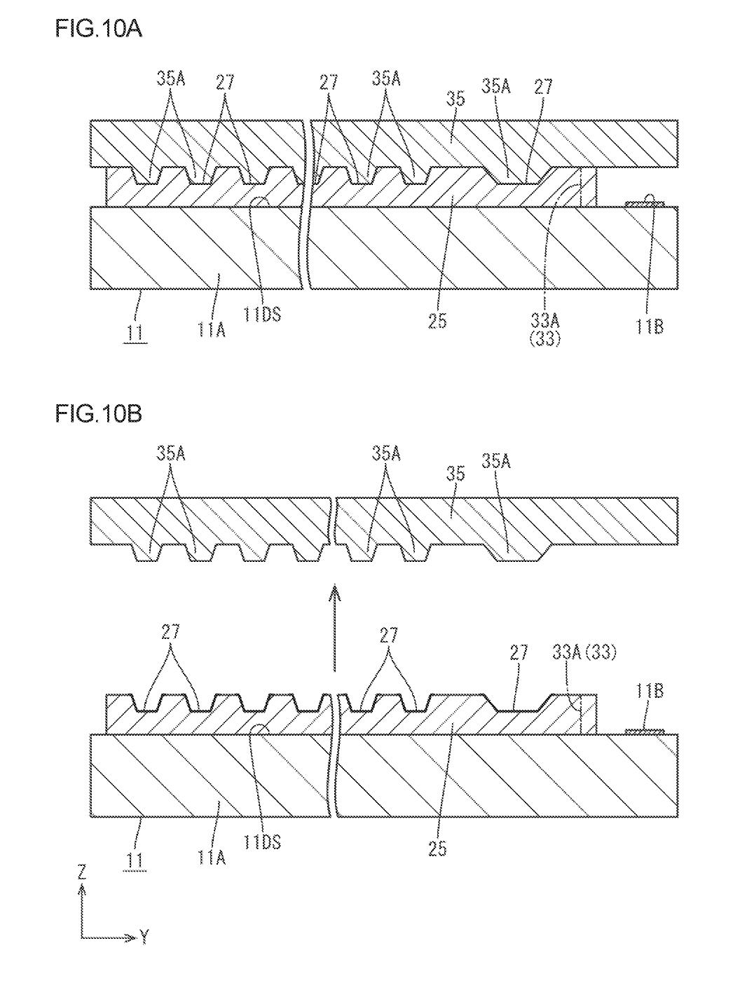

In this case, as shown in FIG. 2, the touch panel 20 in accordance with the present embodiment is provided with the first regulating portion (regulating portion) 33 that is made in contact with the end portion of the first in-print layer 25 to regulate the formation range of the first in-print layer 25 and the second regulating portion (second regulating portion) 34 that is made in contact with the end portion of the second in-print layer 26 to regulate the formation range of the second in-print layer 26. Additionally, in FIG. 2, the first regulating portion 33 and the second regulating portion 34 are indicated by one dot chain lines described in the same layers as the first in-print layer 25 and the second in-print layer 26, and the same is true for the other drawings (FIG. 10A to FIG. 12B and FIG. 14 to FIG. 20B). The first regulating portion 33 is formed on the surface of the organic EL panel 11 prior to the first in-print layer 25, upon manufacturing the touch panel 20. Therefore, at the time of forming the first in-print layer 25, the end portion of the first in-print layer 25 is made in contact with the first regulating portion 33 that has been preliminarily formed, thereby making it possible to regulate the formation range of the first in-print layer 25. In the same manner, the second regulating portion 34 is formed on the surface of the first in-print layer 25 prior to the second in-print layer 26, upon manufacturing the touch panel 20. Therefore, at the time of forming the second in-print layer 26, the end portion of the second in-print layer 26 is made in contact with the second regulating portion 34 that has been preliminarily formed, thereby making it possible to regulate the formation range of the second in-print layer 26. In this case, in the conventional configuration, in order to avoid the portion of the first conductive layer to be formed into the terminal from being covered with the second matrix layer, it is necessary to dispose the above-mentioned portion to be formed into the terminal out of the assumed maximum formation range of the second matrix layer, and for this reason, the frame edge width of the touch screen becomes too large. In contrast, in the present embodiment, by regulating the respective formation ranges of the first in-print layer 25 and the second in-print layer 26 by the first regulating portion 33 and the second regulating portion 34, it becomes possible to prevent the first in-print layer 25 and the second in-print layer 26 from being formed in an excessively expanded state than has been assumed. Thus, the frame edge width of the touch panel 20 can be made narrower than in the prior art so that the frame edge widths of the touch panel 20 and the organic EL display device 10 can be made desirably narrower.

As shown in FIG. 2, the first regulating portion 33 is disposed in the Y-axis direction in a manner so as to be interposed between the first in-print layer 25 and the panel terminal 11B on the organic EL panel 11. With this configuration, at the time of forming the first in-print layer 25, since the formation range of the first in-print layer 25 on the surface of the organic EL panel 11 is regulated by the first regulating portion 33, it is possible to prevent the first in-print layer 25 from being expanded to the region to be overlapped with the panel terminal 11B. Thus, the panel terminal 11B is maintained in an exposed state without being covered with the first in-print layer 25 so that the display-use flexible substrate 12 to be assembled on the organic EL panel 11 can be connected to the panel terminal 11B without causing any problem. In the same manner, the second regulating portion 34 is disposed in the Y-axis direction in a manner so as to be interposed between the second in-print layer 26 and the first terminal 31A of the first in-print layer 25. With this configuration, at the time of forming the second in-print layer 26, since the formation range of the second in-print layer 26 on the surface of the first in-print layer 25 is regulated by the second regulating portion 34, the second in-print layer 26 is prevented from being expanded to the range to be overlapped with the first terminal 31A. Thus, since the first terminal 31A is maintained in an exposed state without being covered with the second in-print layer 26, the touch panel-use flexible substrate 13 to be assembled on the touch panel 20 can be connected to the first terminal 31A without causing any problem.

As shown in FIG. 5, each of the first regulating portions 33 is disposed so as to be made in contact with each of the end portions of three sides in the first in-print layer 25 having a square shape when seen in a plan view. The first regulating portion 33 is constituted by a first long side regulating portion 33A that is made in contact with the end portion of one of the long sides (panel end portion 11B side of the organic EL panel 11) of the peripheral end portions of the first in-print layer 25 and a pair of first short side regulating portions 33B that are made in contact with the respective end portions on a pair of short sides thereof. With this arrangement, at the time of forming the first in-print layer 25 upon manufacturing the touch panel 20, the material for the first in-print layer 25 is regulated from being expanded toward the panel terminal 11B side by the first long side regulating portion 33A, while the material for the first in-print layer 25 is also directed to the end portion side of the other long side (side opposite to the panel terminal 11B side) on the organic EL panel 11 by the paired first short side regulating portions 33B. Moreover, even in the case when an excessive portion is generated in the material for the first in-print layer 25, the excessive portion can be released from the end portion side of the other long side on which no first regulating portion 33 is formed. Thus, the thickness of the first in-print layer 25 can be uniformed within the in-plane.

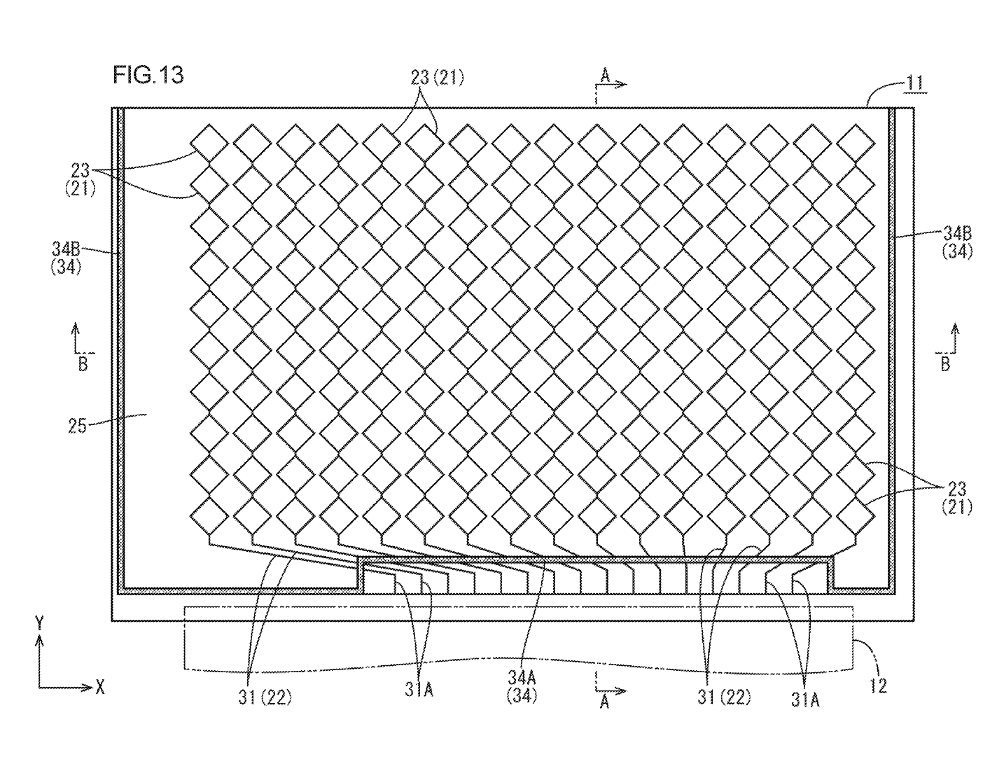

As shown in FIG. 13, each of the second regulating portions 34 is disposed so as to be made in contact with each of the end portions of three sides in the second in-print layer 26 having a square shape when seen in a plan view. The second regulating portion 34 is constituted by a second long side regulating portion 34A that is made in contact with the end portion of one of the long sides (first terminal 31A side of the first in-print layer 25) of the peripheral end portions of the second in-print layer 26 and a pair of second short side regulating portions 34B that are made in contact with the respective end portions on a pair of short sides thereof. The second long side regulating portion 34A is disposed on the outer end of the first in-print layer 25 on the non-formation portion of the first terminal end 31A on one of the end portions on the long side on the first in-print layer 25; however, on the formation portion of the first terminal end 31A, it is disposed on a position recessed inward from the outer end (first terminal 31A) of the first in-print layer 25. With this arrangement, at the time of forming the second in-print layer 26 upon manufacturing the touch panel 20, the material for the second in-print layer 26 is regulated from being expanded toward the first terminal 31A side by the second long side regulating portion 34A, while the material for the second in-print layer 26 is also directed to the end portion side of the other long side (side opposite to the first terminal 31A side) on the first in-print layer 25 by the paired second short side regulating portions 34B. Moreover, even in the case when an excessive portion is generated in the material for the second in-print layer 26, the excessive portion can be released from the end portion side of the other long side on which no second regulating portion 34 is formed. Thus, the thickness of the second in-print layer 26 can be uniformed within the in-plane.

Moreover, the first regulating portion 33 and the second regulating portion 34 are made of an ultraviolet ray curable resin material in the same manner as in the first in-print layer 25 and the second in-print layer 26. More preferably, the first regulating portion 33 and the second regulating portion 34 are made of the same materials as the first in-print layer 25 and the second in-print layer 26. With this arrangement, a device (ultraviolet ray irradiation device) for curing the first regulating portion 33 and the second regulating portion 34 at the time of manufacturing the touch panel 20 can be compatibly used as a device for curing the first in-print layer 25 and the second in-print layer 26, and the conditions or the like for curing can be easily set.

The organic EL display device 10 in accordance with the present embodiment has the configuration as described above, and the following description will explain a method of producing the touch panel 20 installed in the organic EL panel 11 constituting the organic EL display device 10. The method of producing the touch panel 20 is provided with a first regulating portion forming step (regulating portion formation step) of forming the first regulating portion 33 on the display surface 11DS (surface) of the organic EL panel 11; a first in-print layer forming step (in-print layer forming step) of forming a first in-print layer 25 on the display surface 11DS of the organic EL panel 11; a first groove forming step (groove formation step, first in-print step) of forming a first conductive layer formation groove 27 by partially recessing the surface of the first in-print layer 25; a first conductive layer forming step (conductive layer forming step) of forming a first conductive layer 28 inside the first conductive layer formation groove 27; a second regulating portion forming step (second regulating portion forming step) of forming the second regulating portion 34 on the surface side on the formation surface of the first conductive layer formation groove 27 on the first in-print layer 25; a second in-print layer forming step (second in-print layer forming step) of forming the second in-print layer 26 on the surface side of the formation surface of the first conductive layer formation groove 27 on the first in-print layer 25; a second groove forming step (second groove forming step, second in-print step) of forming a second conductive layer formation groove 29 by partially recessing the surface of the second in-print layer 26; and a second conductive layer forming step (second conductive layer forming step) of forming a second conductive layer 30 inside the second conductive layer formation groove 29.

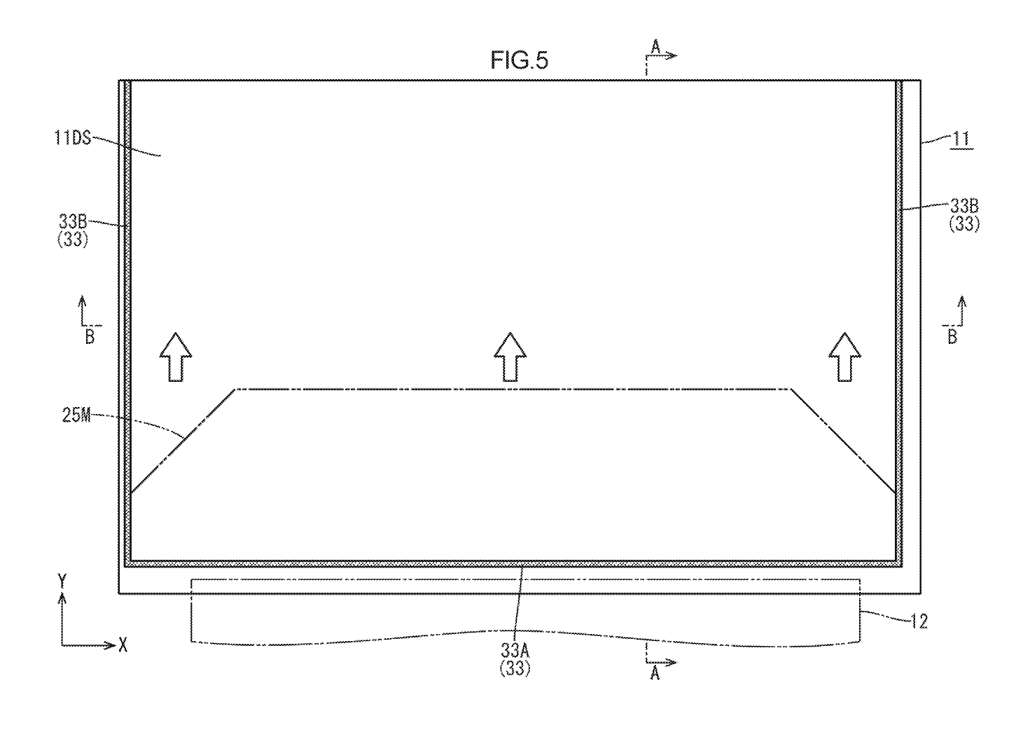

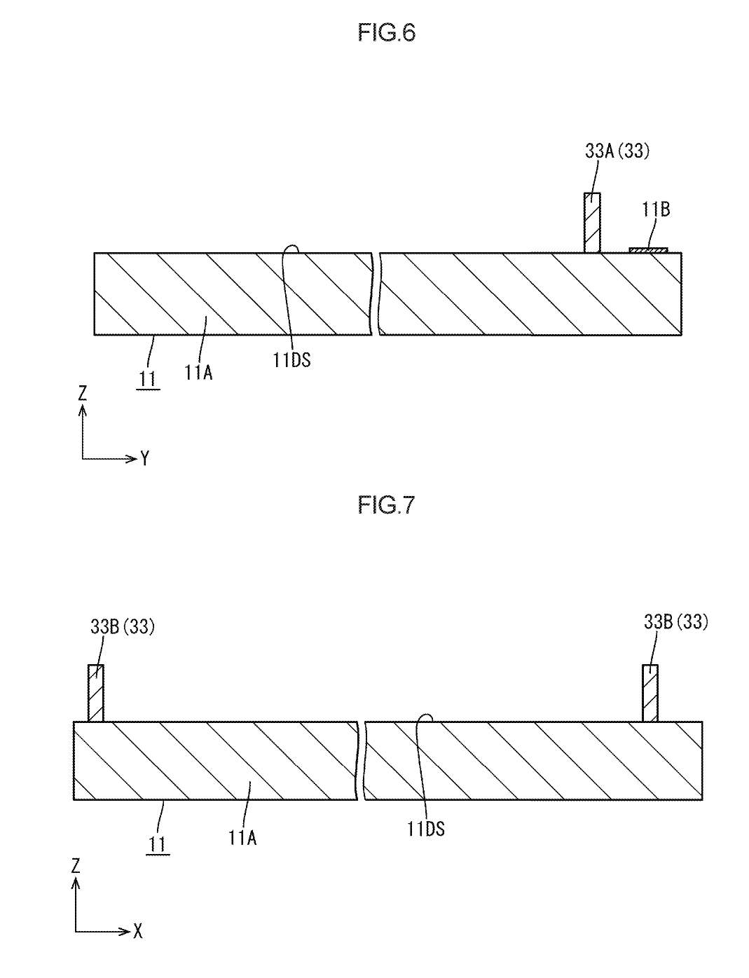

The first regulating portion forming step is carried out prior to the first in-print layer formation process. In the first regulating portion forming step, as shown in FIG. 5, by using, for example, a dispenser device (not shown), onto the display surface 11DS of the organic EL panel 11, an ultraviolet ray curable resin material in an uncured state (material for first regulating portion 33) is applied, and by this arrangement, the first regulating portion 33 in the uncured state is drawn and formed thereon with high positional precision. At this time, by relatively changing the positions of the dispenser device and the organic EL panel 11, the first regulating portion 33 is disposed in a manner so as to extend over three sides including the paired short side portions and one (panel terminal 11B side) of the long side portions of the peripheral end portions of the organic EL panel 11. The first regulating portion 33 partitions a formation planning range of the first in-print layer 25. In this stage, the thickness (height) of the first regulating portion 33 is set to a value greater than 10 μm corresponding to the thickness of the first in-print layer 25, as shown in FIG. 6 and FIG. 7. The first regulating portion 33 that is drawn and formed becomes a semi-cured state by irradiation with an ultraviolet ray for curing for a predetermined period of time projected from an ultraviolet ray irradiation device (not shown). The first regulating portion 33 set to this semi-cured state can be deformed by applying a force that is a predetermined value or more; however, since it is hardly deformed by the corresponding force or less, a fixed shape retaining property is exerted.

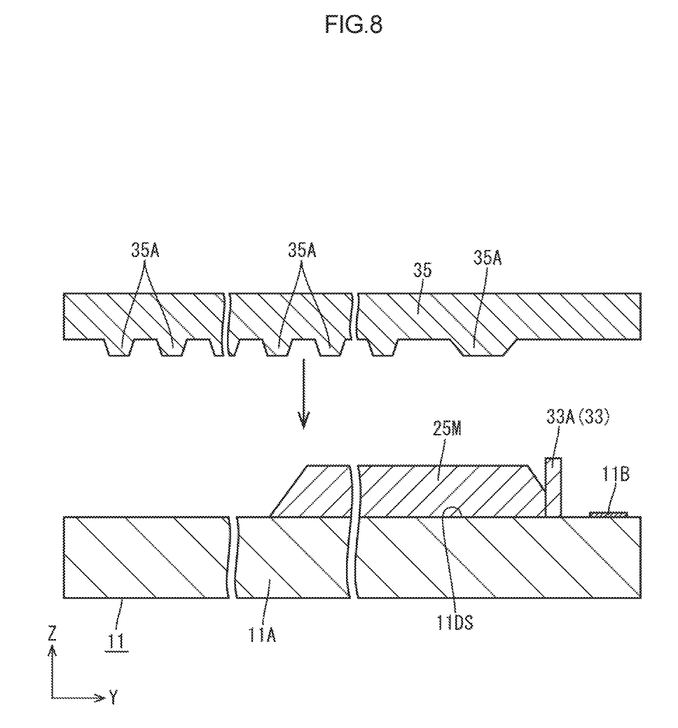

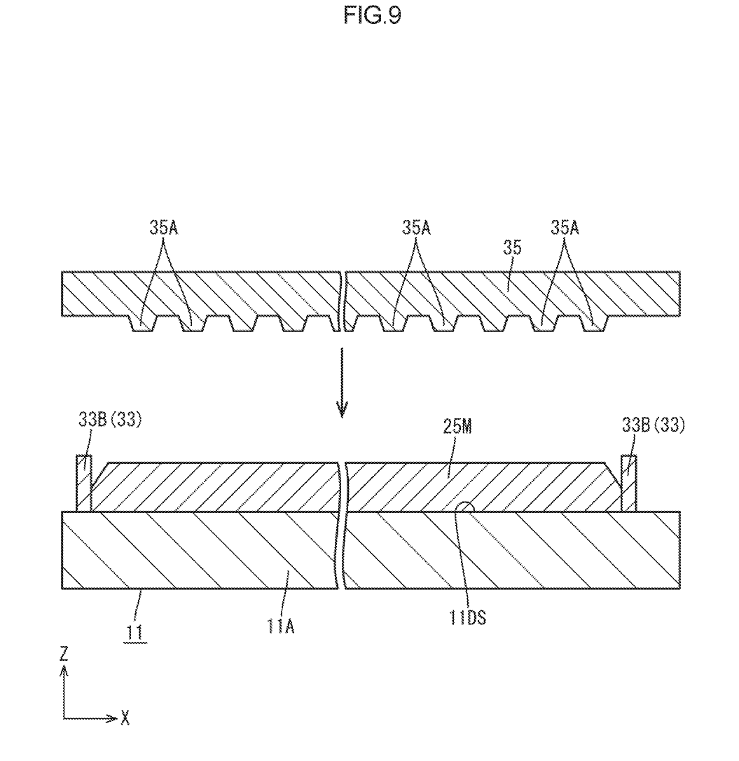

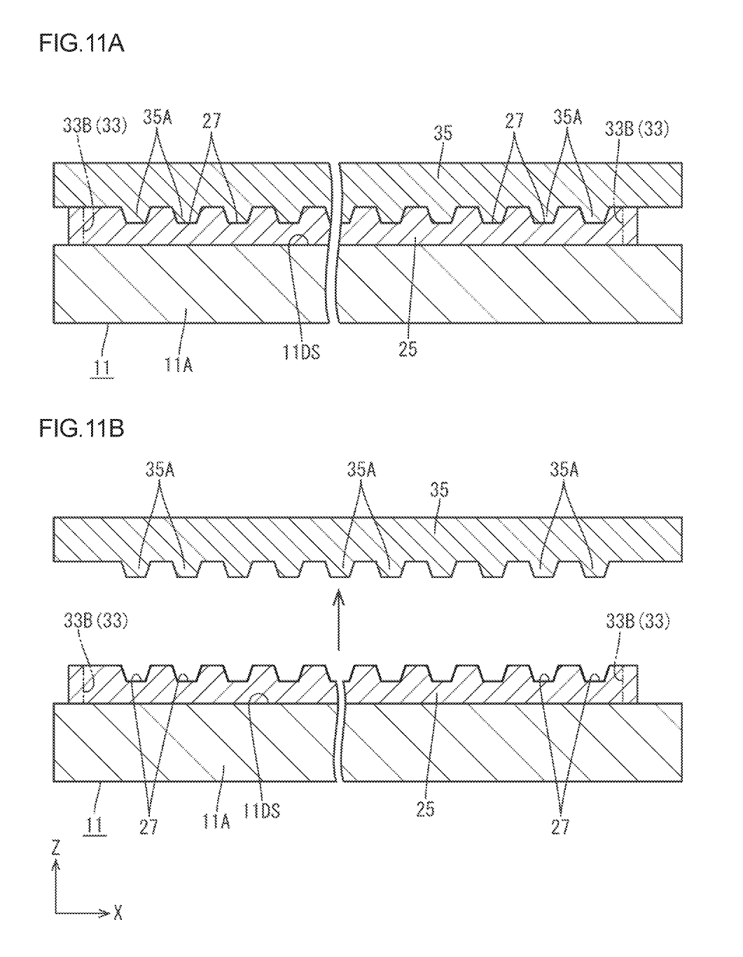

In the first in-print layer forming step, as shown in FIG. 8 and FIG. 9, the first in-print layer 25 made of an ultraviolet ray curable resin material 25M is formed on the display surface 11DS of the organic EL panel 11. At this time, by using an applying device such as a dispenser or the like, the ultraviolet ray curable resin material (material for the first in-print layer 25) 25M in an uncured state is applied onto the surface of the organic EL panel 11. At this time, as shown by a two dots chain line of FIG. 5, the ultraviolet ray curable resin material 25M is applied along the first long side regulating portion 33A in the vicinity of the first long side regulating portion 33A on the first regulating portion 33. Next, in the first groove forming step, as shown in FIG. 10A and FIG. 11A, a first in-print plate (first pattern mask, first transfer plate) 35 is pushed down onto the surface of the ultraviolet ray curable resin material 25M in an uncured state. At this time, by a force exerted from the first in-print plate 35, the ultraviolet ray curable resin material 25M in the uncured state is pushed and expanded along an arrow line shown in FIG. 5; therefore, its flowing movement is smoothly guided by a pair of first short side regulating portions 33B in the first regulating portion 33. The first regulating portion 33 is not formed on the other long side portion of the peripheral end portion of the organic EL panel 11; therefore, even in the case when there is an excessive portion of the ultraviolet ray curable resin material 25M, the excessive portion can be externally released from the non-formation portion of the first regulating portion 33. On the other hand, since the first regulating portion 33 is provided with the first long side regulating portion 33A that is disposed on one of the long side portions where the panel terminal 11B of the peripheral end portion of the organic EL panel 11 is disposed, it is possible to regulate the ultraviolet ray curable resin material 25M in the uncured state from expanding toward the panel terminal 11B side. Thus, since the panel end portion 11B is maintained in an exposed state without being covered with the first in-print layer 25, the display-use flexible substrate 12 to be assembled onto the organic EL panel 11 thereafter can be connected to the panel terminal 11B without causing any problems. As described above, since the first in-print layer 25 is formed with a thickness having higher uniformity and is prevented from being formed in an excessively expanded state than assumed, it becomes possible to make the frame edge width of the touch panel 20 narrower than that in the prior art, and consequently to achieve a narrow frame edge of the touch panel 20 and the organic EL display device 10.

Furthermore, the first regulating portion 33 to be set to a semi-cured state is compressed and deformed together with the first in-print layer 25 by a force exerted from the first in-print plate 35, as shown in FIG. 10A and FIG. 11A, to have a thickness of about 10 μm. The first regulating portion 33 has its substantially entire region integrally formed with the first in-print layer 25 in a state being made in contact with the end portion of the first in-print layer 25. In this case, the first in-print plate 35 is provided with minute protrusions 35A formed by transferring the shape of the first conductive layer formation groove 27 on the contact surface (formation surface) relative to the first in-print layer 25. Therefore, the first in-print layer 25 onto which the first in-print plate 35 is pushed has its portion where the protrusions 35A are pressed formed into recessed portions. When an ultraviolet ray is applied onto the first in-print layer 25 and the first regulating portion 33 in this state, the ultraviolet ray curable resin material 25M of the first in-print layer 25, which was in an uncured state, is completely cured, and the first regulating portion 33, which was in a semi-cured state, is completely cured. Thereafter, when the first in-print plate 35 is separated from the first in-print layer 25, as shown in FIG. 10B and FIG. 11B, the portion of the first in-print layer 25 into which the protrusions 35A of the first in-print plate 35 are pressed becomes the first conductive layer formation groove 27. That is, the first in-print plate 35 is transferred onto the first in-print layer 25 so that the first conductive layer formation groove 27 is formed.

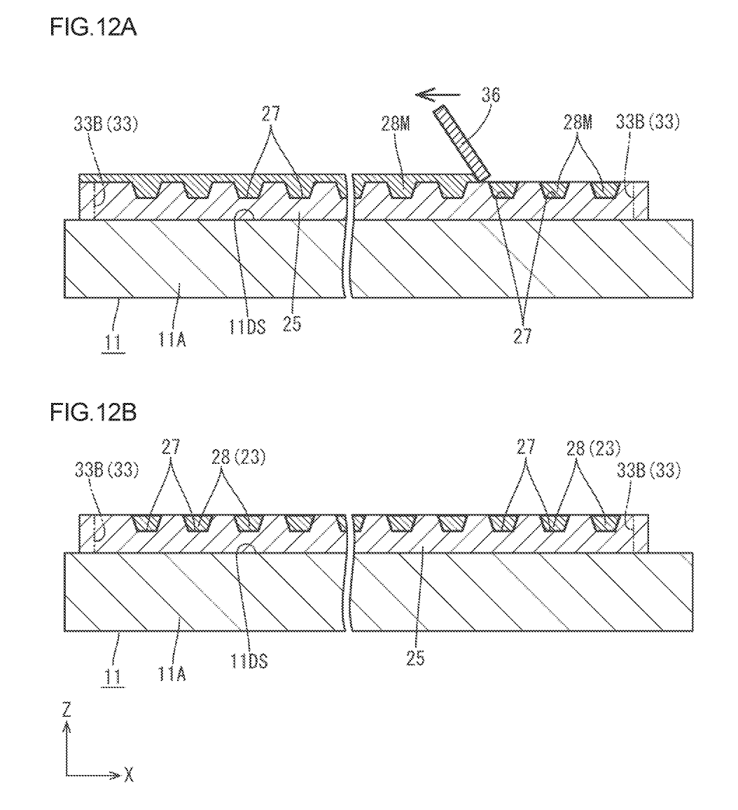

As shown in FIG. 12A, in the first conductive layer forming step, a material 28M for a first conductive layer 28 is applied onto the surface of the first in-print layer 25 on which the first conductive layer formation groove 27 has been formed. The material 28M for the first conductive layer 28 is prepared as metal nano-ink formed by dissolving and dispersing nano-particles of a metal material such as silver or the like into a solvent (dissolving agent) made of water, alcohol or the like so as to exert superior flowability or the like. The material 28M for the first conductive layer 28 applied onto the surface of the first in-print layer 25 is filled into the first conductive layer formation groove 27 or disposed out of the first conductive formation groove 27. Thereafter, when a squeegee 36 is allowed to slide along the surface of the first in-print layer 25, as shown in FIG. 12B, the material 28M for the first conductive layer 28 located outside of the first conductive layer formation groove 27 of the surface of the first in-print layer 25 is removed by the squeegee 36; however, the material 28M for the first conductive layer 28 located inside the first conductive layer formation groove 27 remains without being removed by the squeegee 36. Moreover, even when there are some of the large number of the first conductive layer formation grooves 27 in which the inside thereof is not filled with the material 28M of the first conductive layer 28, those grooves 27 are filled with the material 28M for the first conductive layer 28 collected from the outside of the first conductive layer formation grooves 27 by the squeegee 36. Thus, the inside of each of all the first conductive layer formation grooves 27 can be filled with the material 28M for the first conductive layer 28. Thereafter, by evaporating the solvent contained in the material 28M for the first conductive layer 28 by using a drying device, the first conductive layer 28 is formed inside the first conductive layer formation grooves 27. Thus, the first touch electrode 23 and the first peripheral wiring 31 (including the first terminal 31A) made of the first conductive layer 28 are patterned on the surface of the first in-print layer 25 (see FIG. 3). Additionally, the drying temperature in the drying device is set to, for example, about 80° C., and in comparison with that of the photographing process and depositing process carried out in the manufacturing process of the organic EL panel 11, the processing temperature is set to such a low temperature that it becomes possible to avoid adverse effects from being given to structural objects (fluorescent material layer, TFT, pixel electrodes, etc.) installed inside the organic EL panel 11.

The second regulating portion forming step is carried out prior to the second in-print layer forming step. In the second regulating portion forming process, as shown in FIG. 13, by using, for example, a dispenser device (not shown), an ultraviolet ray curable resin (material for the second regulating portion 34) in an uncured state is applied to the surface of the first in-print layer 25, the second regulating portion 34 in the uncured state is drawn and formed thereon with high positional precision. At this time, by relatively changing the positions of the dispenser device and the organic EL panel 11 as well as the first in-print layer 25, the second regulating portion 34 is disposed in a manner so as to extend over three sides including the paired short side portions and one (first terminal 31A side) of the long side portions of the peripheral end portions of the first in-print layer 25. The second regulating portion 34 partitions a formation planning range of the first in-print layer 25. In this stage, the thickness (height) of the second regulating portion 34 is set to a value greater than 10 μm corresponding to the thickness of the second in-print layer 26, as shown in FIG. 14 and FIG. 15. The second regulating portion 34 that is drawn and formed becomes a semi-cured state by irradiation with an ultraviolet ray for curing for a predetermined period of time projected from an ultraviolet ray irradiation device (not shown). The second regulating portion 34 set to this semi-cured state can be deformed by applying a force that is a predetermined value or more; however, since it is hardly deformed by the corresponding force or less, a fixed shape retaining property is exerted.

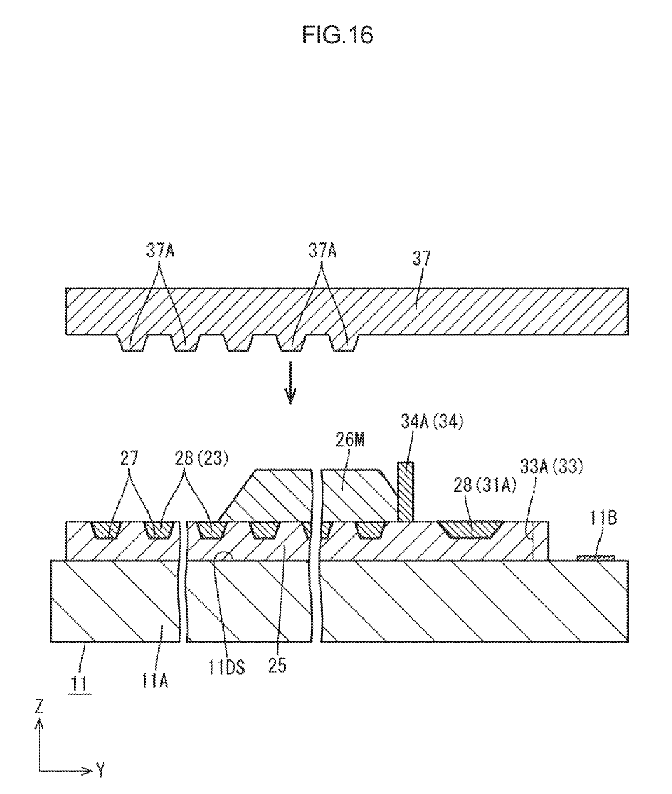

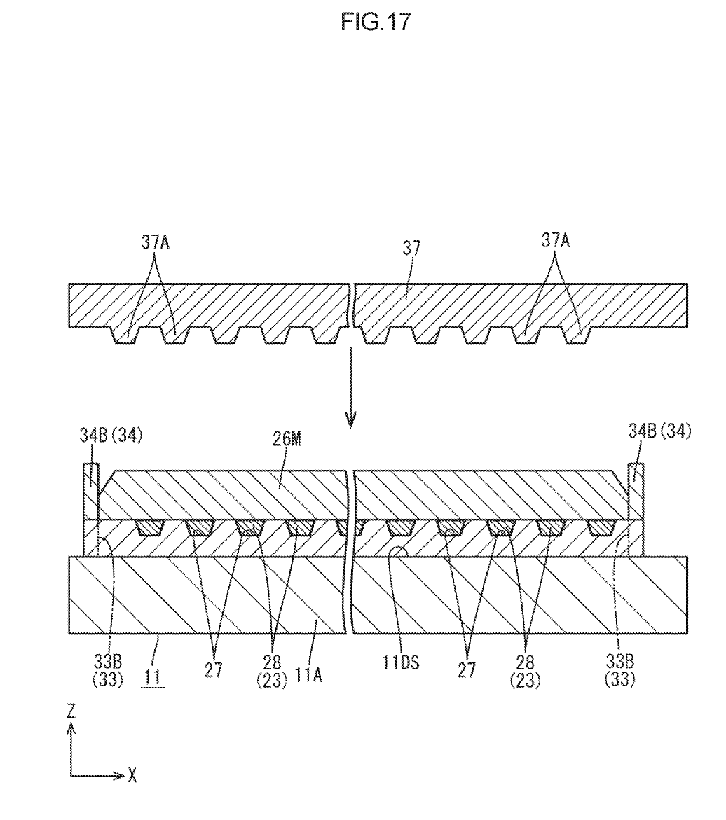

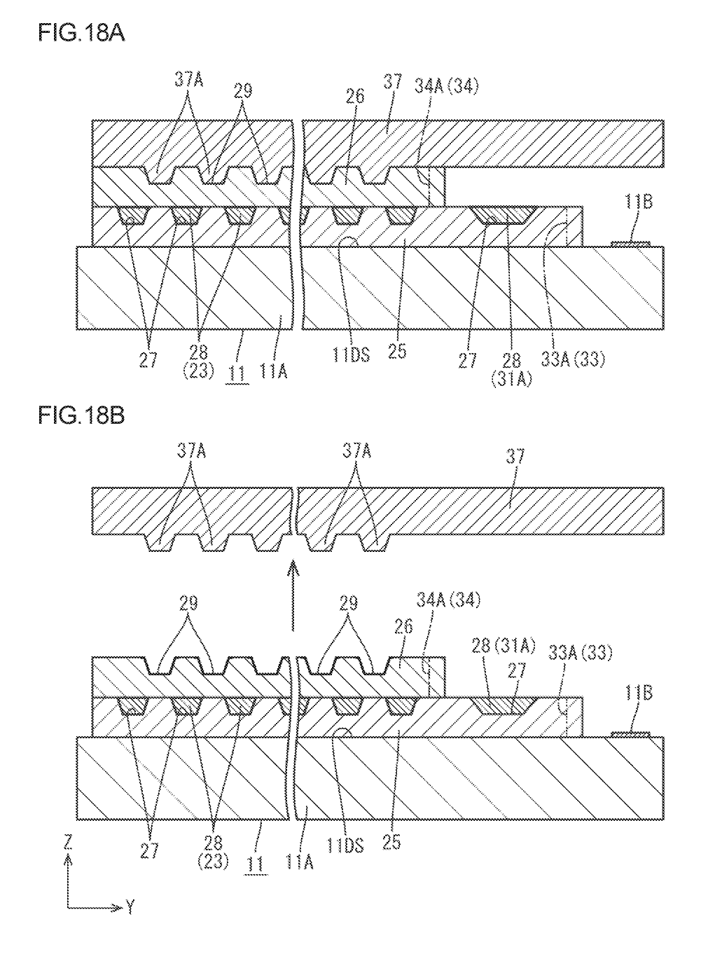

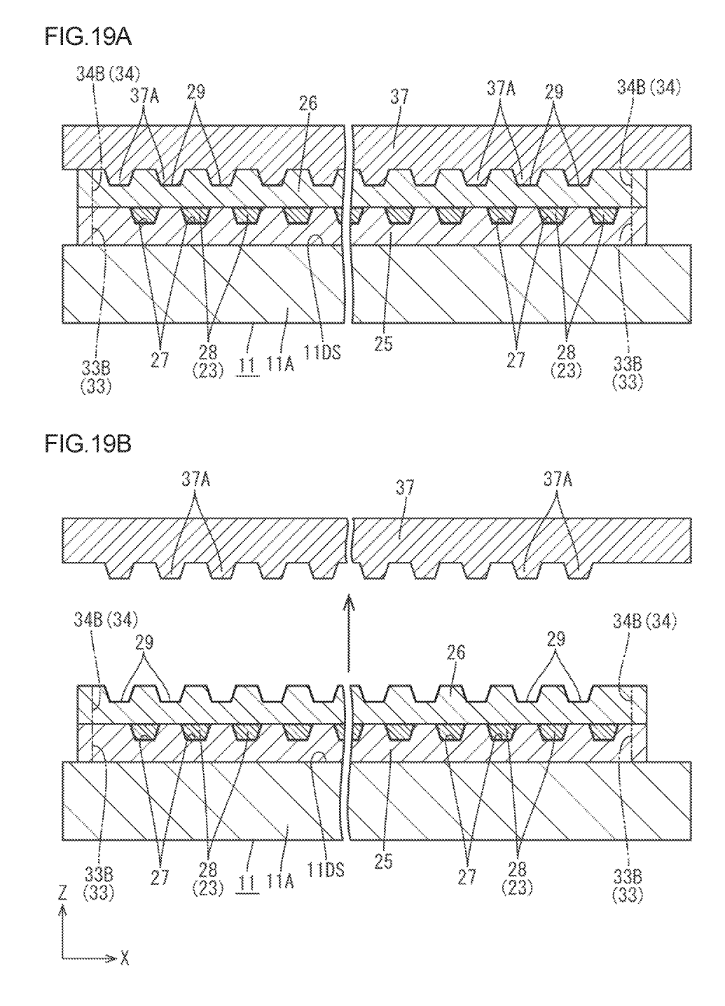

In the second in-print layer forming step, as shown in FIG. 16 and FIG. 17, the second in-print layer 26 made of an ultraviolet ray curable resin material 26M is formed on the surface of the first in-print layer 25. At this time, by using an applying device such as a dispenser or the like, the ultraviolet ray curable resin material (material for the second in-print layer 26) 26M in an uncured state is applied onto the surface of the first in-print layer 25. At this time, the ultraviolet ray curable resin material 26M is applied along the second long side regulating portion 34A in the vicinity of the second long side regulating portion 34A of the second regulating portion 34. Next, in the second groove forming step, as shown in FIG. 18A and FIG. 19A, a second in-print plate (second pattern mask, second transfer plate) 37 is pushed down onto the surface of the ultraviolet ray curable resin material 26M in an uncured state. At this time, by a force exerted from the second in-print plate 37, the ultraviolet ray curable resin material 26M in the uncured state is pushed and expanded, its flowing movement is smoothly guided by a pair of second short side regulating portions 34B in the second regulating portion 34. The second regulating portion 34 is not formed on the other long side portion of the peripheral end portion of the first in-print layer 25; therefore, even in the case when there is an excessive portion of the ultraviolet ray curable resin material 26M, the excessive portion can be externally released from the non-formation portion of the second regulating portion 34. On the other hand, since the second regulating portion 34 is provided with the second long side regulating portion 34A that is disposed on one of the long side portions where the first terminal 31A of the peripheral end portion of the first in-print layer 25 is disposed, it is possible to regulate the ultraviolet ray curable resin material 26M in the uncured state from expanding toward the first terminal 31A side. Thus, since the first terminal 31A is maintained in an exposed state without being covered with the second in-print layer 26, the touch panel-use flexible substrate 13 to be assembled onto the first in-print layer 25 thereafter can be connected to the first terminal 31A without causing any problems. As described above, since the second in-print layer 26 is formed with a thickness having higher uniformity and is prevented from being formed in an excessively expanded state than assumed, it becomes possible to make the frame edge width of the touch panel 20 narrower than that in the prior art, and consequently to achieve a narrow frame edge of the touch panel 20 and the organic EL display device 10.

Furthermore, the second regulating portion 34 to be set to a semi-cured state is compressed and deformed together with the second in-print layer 26 by a force exerted from the second in-print plate 27, as shown in FIG. 18A and FIG. 19A, to have a thickness of about 10 μm. The second regulating portion 34 has its substantially entire region integrally formed with the second in-print layer 26 in a state being made in contact with the end portion of the second in-print layer 26. In this case, the second in-print plate 37 is provided with minute protrusions 37A formed by transferring the shape of the second conductive layer formation groove 29 on the contact surface (formation surface) relative to the second in-print layer 26. Therefore, the second in-print layer 26 onto which the second in-print plate 37 is pushed has its portion where the protrusions 37A are pressed formed into recessed portions. When an ultraviolet ray is applied onto the second in-print layer 26 and the second regulating portion 34 in this state, the ultraviolet ray curable resin material 26M of the second in-print layer 26, which was in an uncured state, is completely cured, and the second regulating portion 34, which was in a semi-cured state, is completely cured. Thereafter, when the second in-print plate 37 is separated from the second in-print layer 26, as shown in FIG. 18B and FIG. 19B, the portion of the second in-print layer 26 into which the protrusions 37A of the second in-print plate 37 are pressed becomes the second conductive layer formation groove 29. That is, the second in-print plate 37 is transferred onto the second in-print layer 26 so that the second conductive layer formation groove 29 is formed.

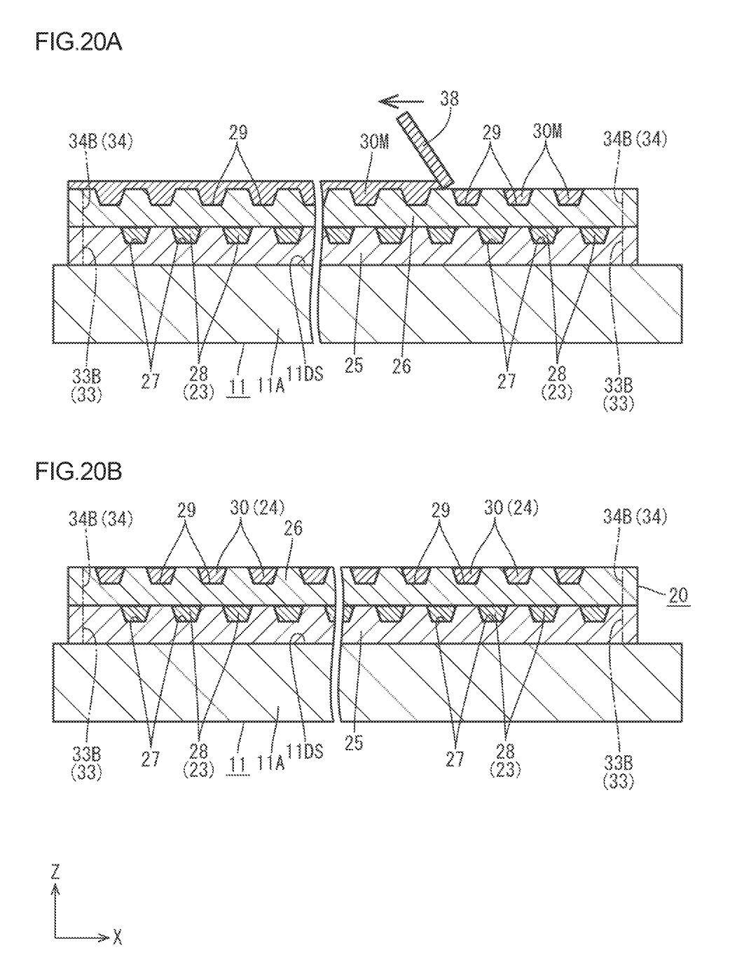

As shown in FIG. 20A, in the second conductive layer forming step, a material 30M for a second conductive layer 30 is applied onto the surface of the second in-print layer 26 on which the second conductive layer formation groove 29 has been formed. The material 30M for the second conductive layer 30 is the same as the material 28M for the first conductive layer 28. In the same manner as in the first conductive layer forming step, when a squeegee 38 is allowed to slide along the surface of the second in-print layer 26 on which the material 30M for the second conductive layer 30 is applied, as shown in FIG. 20B, the material 30M for the second conductive layer 30 located outside of the second conductive layer formation groove 29 of the surface of the second in-print layer 26 is removed by the squeegee 38; however, the material 30M for the second conductive layer 30 located inside the second conductive layer formation groove 29 remains without being removed by the squeegee 38. Thus, the inside of each of all the second conductive layer formation grooves 29 can be filled with the material 30M for the second conductive layer 30. Thereafter, by evaporating the solvent contained in the material 30M for the second conductive layer 30 by using a drying device in the same manner as in the first conductive layer forming step, the second conductive layer 30 is formed inside the second conductive layer formation groove 29. Thus, the second touch electrode 24 and the second peripheral wiring 32 (including the second terminal 32A) made of the second conductive layer 30 are patterned on the surface of the second in-print layer 26 (see FIG. 3). Additionally, the drying temperature in the drying device is set to, for example, about 80° C., in the same manner as in the first conductive layer forming step.

As explained above, the touch panel (substrate) 20 in accordance with the present embodiment is provided with the first in-print layer (in-print layer) 25 having the first conductive layer formation groove (conductive layer formation groove) 27 formed by partially recessing the surface thereof, the first conductive layer (conductive layer) 28 formed inside the first conductive layer formation groove 27, and the first regulating portion (regulating portion) 33 that is disposed so as to be made in contact with the end portion of the first in-print layer 25 to regulate the formation range of the first in-print layer 25.

In this manner, on the surface of the first in-print layer 25, the first conductive layer formation groove 27 as partially recessed portion is formed, and inside the first conductive layer formation groove 27, the first conductive layer 28 is formed. At the time of forming the first in-print layer 25, since the formation range of the first in-print layer 25 is regulated by the first regulating portion 33 disposed so as to be made in contact with the end portion of the first in-print layer 25, it becomes possible to prevent the first in-print layer 25 from being formed in an excessively expanded state. Therefore, in comparison with the conventional configuration in which so as to make the portion to be formed into the terminal of the first conductive layer avoided from being covered with the second matrix layer, the frame edge width of the touch screen becomes wider, the frame edge width can be made narrower, thereby making it possible to desirably provide a narrow frame edge.

Moreover, since the first in-print layer 25 has a substantially square shape, the first regulating portion 33 is disposed so as to be made in contact with the respective end portions of the three sides in the first in-print layer 25. In this manner, the first in-print layer 25 having the substantially square shape is desirably regulated in its formation range by the first regulating portion 33 that is disposed so as to be made in contact with the respective end portions of the three sides thereof. On the other hand, since one side of the end portions of the first in-print layer 25 is not made in contact with the first regulating portion 33, upon forming the first in-print layer 25, an excessive portion of the material for the first in-print layer 25 can be released from the end portion side of the above-mentioned one side. Thus, the thickness of the first in-print layer 25 can be desirably set to a fixed value.

Moreover, the second in-print layer (second in-print layer) 26 having the second conductive layer formation groove (second conductive layer formation groove) 29 that is disposed in an overlapped manner on the formation surface of the first conductive layer formation groove 27 on the first in-print layer 25, and formed by partially recessing the surface, the second conductive layer (second conductive layer) 30 formed inside the second conductive layer formation groove 29 and the second regulating portion (second regulating portion) 34 that is disposed so as to be made in contact with the end portion of the second in-print layer 26 to regulate the formation range of the second in-print layer 26 are prepared. With this arrangement, on the surface of the second in-print layer 26 that is disposed so as to be overlapped with the formation surface of the first conductive layer formation groove 27 on the first in-print layer 25, the second conductive layer formation groove 29 having partially recessed portions is formed and the second conductive layer 30 is formed inside the second conductive layer formation groove 29. At the time of forming the second in-print layer 26, since the formation range of the second in-print layer 26 is regulated by the second regulating portion 34 disposed so as to be made in contact with the end portion of the second in-print layer 26, it becomes possible to prevent the second in-print layer 26 from being formed in an excessively expanded state.

Moreover, the first terminal (terminal) 31A, which is made of one portion of the first conductive layer 28 and disposed at the end portion of the first in-print layer 25, is prepared, and the second in-print layer 26 is disposed so as not to be overlapped with the first terminal 31A, and the second regulating portion 34 is disposed at least between the second in-print layer 26 and the first terminal 31A. With this arrangement, at the time of forming the second in-print layer 26, by regulating the formation range of the second in-print layer 26 by the second regulating portion 34, it becomes possible to prevent the second in-print layer 26 from being disposed so as to be overlapped with the first terminal 31A. Thus, the first terminal 31A is maintained in an exposed state without being covered with the second in-print layer 26 so that an external connection portion or the like can be connected to the first terminal 31A.

Moreover, the first conductive layer 28 and the second conductive layer 30 respectively forma first touch electrode (first position detection electrode) 23 and a second touch electrode (second position detection electrode) 24 at least one portion of which forms an electrostatic capacitance relative to a finger forming a position input body for carrying out a positional input, and the input position by the finger forming the position input body can be detected, and which are mutually kept in a non-overlapped state. With this arrangement, by the first touch electrode 23 and the second touch electrode 24 that are made of the first conductive layer 28 and the second conductive layer 30 and kept in the non-overlapped state, it becomes possible to detect an input position made by a finger serving as a position input body.

Furthermore, the organic EL display device (display device) 10 in accordance with the present embodiment is provided with the above-mentioned touch panel (substrate) 20 and the organic EL panel (display panel) 11 disposed on the surface of the touch panel 20. In accordance with the organic EL display device 10 having this configuration, since the touch panel 20 to be disposed on the surface of the organic EL panel 11 has a narrow frame edge, the organic EL display device 10 is desirably made to have a narrow frame edge so that a superior appearance can be obtained.

Moreover, the panel terminal 11B is formed at the end portion of the organic EL panel 11, and the first regulating portion 33 is disposed at least between the first in-print layer 25 and the panel terminal 11B. With this arrangement, at the time of forming the first in-print layer 25, by regulating the formation range of the first in-print layer 25 by the first regulating portion 33, it becomes possible to prevent the first in-print layer 25 from being disposed to be overlapped with the panel terminal 11B. Thus, the panel terminal 11B is maintained in an exposed state without being covered with the first in-print layer 25 so that it becomes possible to connect an external connection portion or the like to the panel terminal 11B.

Furthermore, the first in-print layer 25 is made of an ultraviolet ray curable resin material. With this arrangement, in comparison with a case in which the first in-print layer is supposedly made of a thermosetting resin material, the production can be performed even when the organic EL panel 11 does not have a high heat resistant property.

Furthermore, the organic EL panel 11 is made of a synthetic resin so as to have flexibility. With this arrangement, in comparison with a case in which the organic EL panel is supposedly made of glass, thereby having no flexibility, since the first in-print layer 25 is made of an ultraviolet ray curable resin material, although the heat resistant property of the organic EL panel 11 is lowered, the production by the use of the in-print technique can be performed. Since the organic EL panel 11 on the surface of which the touch panel 20 is disposed has sufficient flexibility, it is desirably used for a foldable application.

Moreover, the method of producing the touch panel 20 in accordance with the present embodiment is provided with the first in-print layer forming step (in-print layer forming step) of forming the first in-print layer 25, the first groove forming step (groove forming step) for forming the first conductive layer formation groove 27 by partially recessing the surface of the first in-print layer 25, the first conductive layer forming step (conductive layer forming step) for forming the first conductive layer 28 inside the first conductive layer formation groove 27 and the first regulating portion forming step (regulating portion forming step) that is carried out prior to the first in-print layer forming step so as to allow the first regulating portion 33 to be made in contact with the end portion of the first in-print layer 25.

With this arrangement, when the first in-print layer forming step and the first groove forming step are carried out, the first conductive layer formation groove 27 having partially recessed portions is formed on the surface of the first in-print layer 25. When the first conductive layer forming step is carried out, the first conductive layer 28 is formed inside the first conductive layer formation groove 27 of the first in-print layer 25. In the first regulating portion forming step to be carried out prior to the formation of the first in-print layer 25 in the first in-print layer formation process, since the first regulating portion 33 is formed so as to be disposed to be made in contact with the end portion of the first in-print layer 25, the formation range of the first in-print layer 25 is regulated by the first regulating portion 33 at the time when the first in-print layer 25 is formed in the first in-print layer forming step so that the first in-print layer 25 is prevented from being formed in an excessively expanded state. Therefore, in comparison with the conventional configuration in which so as to make the portion to be formed into the terminal of the first conductive layer avoided from being covered with the second matrix layer, the frame edge width of the touch screen becomes wider, the frame edge width can be made narrower, thereby making it possible to desirably provide a narrow frame edge.

Moreover, in the first regulating portion forming step, the first regulating portion 33 made of a curable material is set to be a semi-cured state. With this arrangement, since upon carrying out the first regulating portion forming step, the first regulating portion 33 in the semi-cured state is formed so that in the first in-print layer forming step to be carried out thereafter, the formation range of the first in-print layer 25 is desirably regulated by the first regulating portion 33 in the semi-cured state.

Furthermore, since in the first regulating portion forming step, the thickness of the first regulating portion 33 is made thicker than the thickness of the first in-print layer 25, and in the first in-print layer forming step, a curable material is used as a material for the first in-print layer 25, and the curable material is compressed and deformed together with the first regulating portion 33 in the semi-cured state. With this arrangement, the first regulating portion 33, which is formed with a thickness larger than the thickness of the first in-print layer 25 in the first regulating portion forming step, and set to the semi-cured state, is compressed and deformed together with the curable material corresponding to the material for the first in-print layer 25 in the first in-print layer forming step so as to be integrally formed with the first in-print layer 25. Thus, the first in-print layer 25 whose thickness is uniformed can be obtained, and the border line between the first in-print layer 25 and the first regulating portion 33 becomes hardly recognizable to provide a superior appearance.

Moreover, in the first regulating portion forming step, the first regulating portion 33 is drawn and formed by using a dispenser device. With this arrangement, since the first regulating portion 33 can be disposed with high precision, a desirable configuration can be achieved in an attempt to make a frame edge narrower.

### Second Embodiment

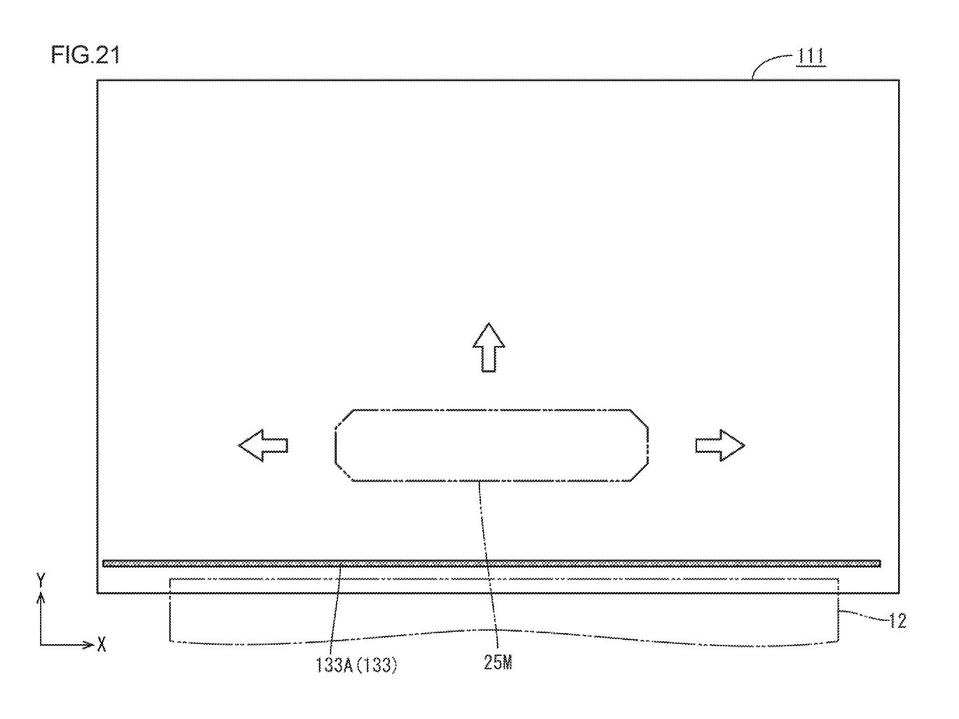

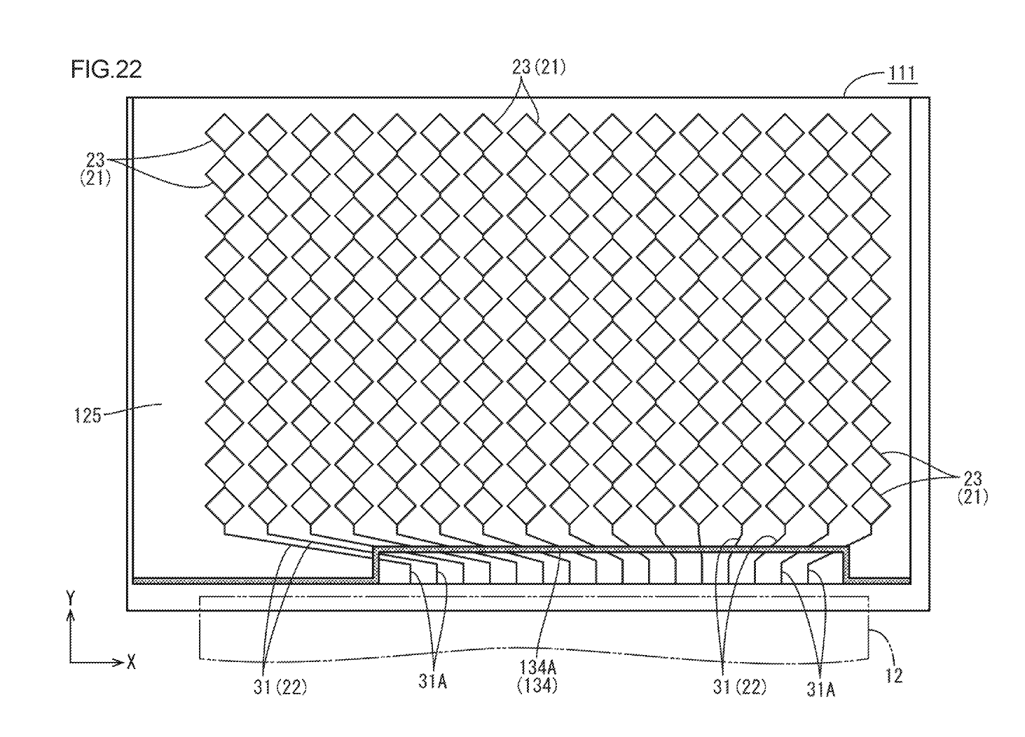

Referring to FIG. 21 and FIG. 22, explanation will be given to a second embodiment of the present invention. In the second embodiment, the formation ranges of a first regulating portion 133 and a second regulating portion 134 are changed. Additionally, with respect to the same structure, function and effect as those of the aforementioned first embodiment, overlapped explanations will be omitted.

As shown in FIG. 21, the first regulating portion 133 in accordance with the present embodiment is selectively disposed only one of long side portions on which the panel terminal (not shown) of the peripheral end portions of the organic EL panel 111 is disposed. That is, the first regulating portion 133 is made of only the first long side regulating portion 133A that extends in the X-axis direction. In this configuration also, by regulating the formation range of the first in-print layer 125 by the first regulating portion 133, it becomes possible to prevent the first in-print layer 125 from being disposed and overlapped with the panel terminal. On the other hand, as shown in FIG. 22, the second regulating portion 134 is selectively disposed only one of long side connection portions on which the first panel terminal (not shown) of the peripheral end portions of the first in-print layer 125 is disposed. That is, the second regulating portion 134 is made of only the second long side regulating portion 134A that extends in the X-axis direction. In this configuration also, by regulating the formation range of the second in-print layer by the second regulating portion 134, it becomes possible to prevent the second in-print layer from being disposed in an overlapped state with the panel terminal.

### Third Embodiment

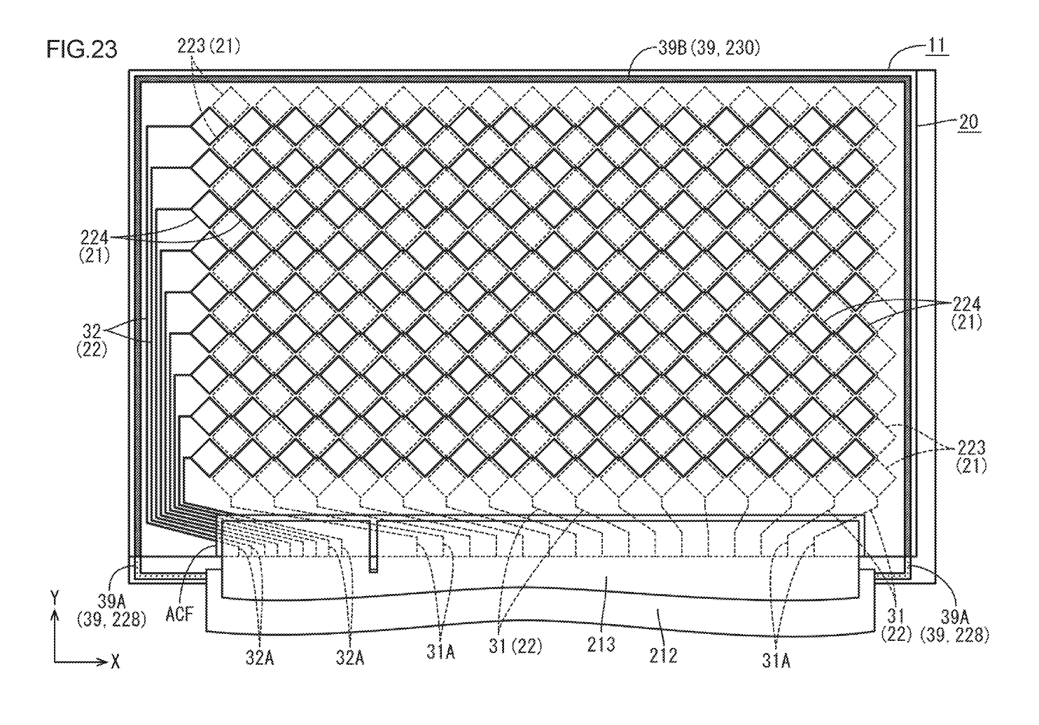

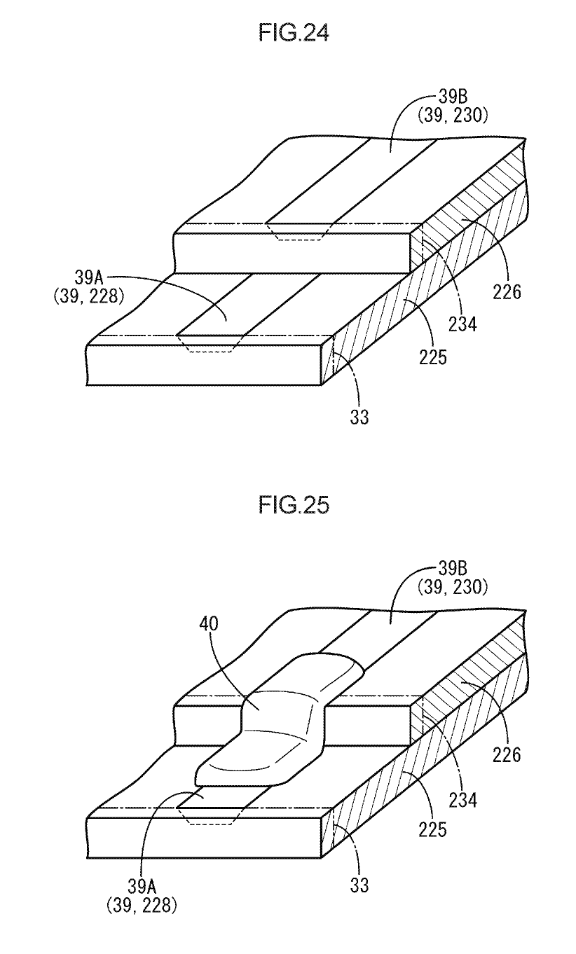

Referring to FIG. 23 and FIG. 24, explanation will be given to a third embodiment of the present invention. In the third embodiment, a configuration in which to the configuration described in the first embodiment, a ground wiring 39 and a conductive paste 40 are added is shown. Additionally, with respect to the same structure, function and effect as those of the aforementioned first embodiment, overlapped explanations will be omitted.

As shown in FIG. 23 and FIG. 24, portions of a first conductive layer 228 and a second conductive layer 230 in accordance with the present embodiment constitute the grand wiring 39. The grand wiring 39, which transmits a ground signal supplied from a display-use flexible substrate 212, has a function, such as, for example, for preventing electric noise from entering from the outside, or for shielding an electric field that can be generated between a first touch electrode 223 and a second touch electrode 224. The ground wiring 39 is constituted by a first ground wiring (ground wiring) 39A composed of the first conductive layer 228 and a second ground wiring (second ground wiring) 39B composed of the second conductive layer 230, and between the first ground wiring 39A and the second ground wiring 39B, a step difference corresponding to the thickness of the second in-print layer 226 is generated. Additionally, in FIG. 23, the first ground wiring 39A and the second ground wiring 39B are illustrated as different network patterns. Therefore, in the present embodiment, as shown in FIG. 25, the conductive paste 40 is installed in a manner so as to straddle between the first grand wiring 39A and the second ground wiring 39B. The conductive paste 40 is made of a paste-state material containing a conductive material, such as, for example, silver or the like. The conductive paste 40 is applied in a manner so as to ride over a step difference generated between the first ground wiring 39A and the second ground wiring 39B so that the first ground wiring 39A and the second ground wiring 39B are electrically connected, thereby allowing the ground wiring 39 to conduct. Additionally, in FIG. 23 and FIG. 24, the conductive paste 40 is not illustrated.

As shown in FIG. 24, the first ground wiring 39A disposed on the first in-print layer 225 is disposed so as not to be overlapped with the second in-print layer 226. In order to form this configuration, the second regulating portion 234 is disposed so as to be interposed between the second in-print layer 226 and the first ground wiring 39A. With this arrangement, at the time of forming the second in-print layer 226, by regulating the formation range of the second in-print layer 226 by the second regulating portion 34, it becomes possible to prevent the second in-print layer 226 from being disposed so as to be overlapped with the first ground wiring 39A. Thus, since the first ground wiring 39A is maintained in the exposed state without being covered with the second in-print layer 226, the conductive paste 40 to be applied in a manner so as to straddle between the first in-print layer 225 and the second in-print layer 226 can be thereafter connected to the first ground wiring 39A, as shown in FIG. 25, without causing any problems.

As explained above, in accordance with the present embodiment, the first conductive layer 228 and the second conductive layer 230 at least respective portions of which form the first ground wiring (ground wiring) 39A and the second ground wiring (second ground wiring) 39B that are ground-connected with each other, are provided with a conductive paste 40 that is disposed so as to straddle between the first in-print layer 225 and the second in-print layer 226 and to be connected to the first ground wiring 39A and the second ground wiring 39B. With this arrangement, the first ground wiring 39A and the second ground wiring 39B that are respectively made of the first conductive layer 228 and the second conductive layer 230 are connected to the conductive paste 40 that is disposed so as to straddle between the first in-print layer 225 and the second in-print layer 226, thereby ground-connected with each other.

Moreover, the second in-print layer 226 is disposed so as not to be overlapped with the first ground wiring 39A, and the second regulating portion 234 is disposed at least between the second in-print layer 226 and the first ground wiring 39A. With this arrangement, at the time of forming the second in-print layer 226, by regulating the formation range of the second in-print layer 226 by the second regulating portion 34, it becomes possible to prevent the second in-print layer 226 from being disposed so as to be overlapped with the first ground wiring 39A. Thus, the first ground wiring 39A is maintained in the exposed state, without being covered with the second in-print layer 226, so that the conductive paste 40 is more positively connected to the first ground wiring 39A.

### OTHER EMBODIMENTS

The technology described herein is not limited to the embodiments described above with reference to the drawings. The following embodiments may be included in the technical scope.

(1) In the above-mentioned respective embodiments, a configuration in which the first regulating portion is disposed on the three sides or one side on the peripheral edge portion of the organic EL panel is exemplified; however, the first regulating portion may be disposed on desired two sides on the peripheral edge portion of the organic EL panel. Moreover, the first regulating portion may be disposed on four sides on the peripheral edge portion of the organic EL panel, that is, on all the peripheral edge portion thereof.

(2) In the above-mentioned respective embodiments, a configuration in which the second regulating portion is disposed on the three sides or one side on the peripheral edge portion of the second in-print layer is exemplified; however, the second regulating portion may be disposed on desired two sides on the peripheral edge portion of the second in-print layer. Moreover, the second regulating portion may be disposed on four sides on the peripheral edge portion of the second in-print layer, that is, on all the peripheral edge portion thereof.

(3) In addition to the above-mentioned embodiments, at the time of forming the respective regulating portions and the respective in-print layers, a silk screen printing method or the like may be used. In addition to these, specific formation methods of the respective constituent connection portions may be changed on demand.

(4) In addition to the above-mentioned embodiments, specific numeric values, such as the thickness of the respective regulating portions and the respective in-print layers, the thickness of the organic EL panel, the thickness of the polarizing plate and the like, may be changed on demand. In the same manner, specific numeric values, such as the depth, the line width and the like of the respective conductive layers, may be changed on demand. In the same manner, specific numeric values, such as external dimensions of the respective touch electrodes, may be changed on demand.

(5) In the above-mentioned embodiments, a touch panel having a configuration in which the first in-print layer and the second in-print layer are stacked is exemplified; however, a touch panel in which a touch panel pattern is formed on a single layer of an in-print layer may be used.

(6) In contrast to the above-mentioned (5), three or more in-print layers may be stacked.

(7) In the above-mentioned embodiments, a touch panel is exemplified as “substrate”; however, in addition to the touch panel, for example, a shielding connection portion for shielding an electromagnetic wave generated from an organic EL panel may be applied as “substrate” in the present invention. For example, such a shielding connection portion is assembled and formed in a mesh state in the same manner as in the respective embodiments where the conductive layer is formed on the surface of a single layer of the in-print layer, and compatibly has a light transmitting function and a shielding function. Additionally, specific configurations of the shielding connection portion may be changed on demand into another mode other than the above-mentioned embodiments.

(8) In the above-mentioned embodiments, a single layer structure of the first conductive layer and the second conductive layer is exemplified; however, the first conductive layer and the second conductive layer may have a stacked structure of a plurality of layers. For example, the first conductive layer and the second conductive layer may have a stacked structure in which a metal layer composed of a metal material is placed on the lower layer side (deep layer side) and a light absorbing conductive layer made of a conductive material having a higher light absorbing rate than the metal layer is placed on the upper layer side (surface layer side) may be used, and with this arrangement, it is possible to obtain superior conductivity and an external light reflection suppressing function exerted by the light absorbing conductive layer. Additionally, specific stacked layer structures of the first conductive layer and the second conductive layer are not intended to be limited by these, and may be modified on demand.

(9) The above-mentioned embodiments have exemplified a case in which as the material for the first conductive layer and the second conductive layer, a metal nano-ink using silver is adopted; however, a conductive paste, such as a gold nano-ink, a cupper nano-ink, a silver paste or the like, or black colored fullerene ink, carbon ink, carbon-based material ink or the like may be used, and moreover, a hybrid ink formed by mixing the metal nano-ink with any one of fullerence ink, carbon ink and carbon-based material ink may be used.

(10) The above-mentioned embodiments have exemplified a case in which the first regulating portion and the second regulating portion, as well as the first in-print layer and the second in-print layer, are made of the same material; however, these may be made of different materials. In this case also, the characteristics of the materials (ultraviolet ray curable characteristic or the like) may be commonly set, with the specific material names, compositions or the like being desirably made different; however, the present invention is not particularly limited by these.

(11) The above-mentioned embodiments have exemplified a case in which an ultraviolet ray curable resin material is used as the material for the first regulating portion and the second regulating portion; however, in addition to this, as the material for the first regulating portion and the second regulating portion, a visible light ray curable resin material (one type of photocurable resin material, which is cured by irradiation with visible light ray), a thermosetting resin material, a thermoplastic resin material or the like may be used.

(12) The above-mentioned embodiments have exemplified a case in which as the material for the first in-print layer and the second in-print layer, an ultraviolet curable resin material is used; however, in addition to these, as the first in-print layer and the second in-print layer, a visible light ray curable resin material (one type of photocurable resin material, which is cured by irradiation with visible light ray), a thermosetting resin material, a thermoplastic resin material or the like may be used.

(13) In addition to the above-mentioned embodiments, of course, the aligning direction of the first touch electrodes and the aligning direction of the second touch electrodes may be exchanged with each other.

(14) The above-mentioned embodiments have exemplified a case in which the plane shape of the touch electrode has a rhombic shape; however, in addition to this, the plane shape of the touch electrode may be changed to a square shape, a circular shape, a polygonal shape of pentagonal shape or more, etc. on demand.

(15) In the above-mentioned embodiments, a touch panel pattern of a mutual capacitance system is exemplified; however, the present invention may be applied to a touch panel pattern of a self capacitance system.

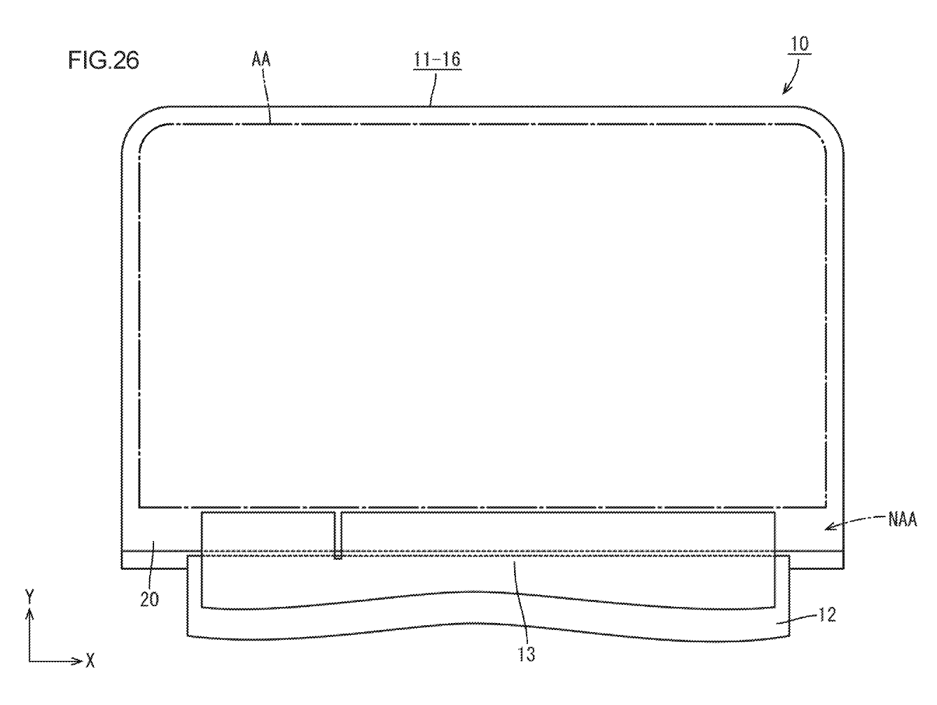

(16) The above-mentioned embodiments have exemplified a case in which the plane shape of the organic EL display device has a rectangular shape with a laterally extended length; however, in addition to this, a rectangular shape with a longitudinally extended length, a square shape or the like, and moreover, a non-rectangular shape, such as a circular shape, an elliptical shape, a trapezoidal shape or the like, may be used. Furthermore, the plane shape of the organic EL display devices 11 to 16 may be a substantially square shape with two corner portions having semi-round shapes, as shown in FIG. 26, and in this case, two corner portions of the display area AA also have substantially square shapes having semi-round shapes. Additionally, the number of the corner portions having semi-round shapes may be changed on demands, in addition to two, and any of the plane shapes have substantially square shapes.

(17) The above-mentioned embodiments have exemplified a case in which the base member of the organic EL panel is made of a synthetic resin; however, the base member of the organic EL panel may be made of glass.

(18) The above-mentioned embodiments have exemplified a case in which a touch panel is integrally formed with a display device (organic EL display device); however, the touch panel may be integrally formed with a device (for example, touch pad) other than the display device.

(19) The above-mentioned embodiments have exemplified an organic EL display device in which an organic EL panel is used as a display panel; however, a liquid crystal display device using a liquid crystal panel as a display panel may be used. Moreover, in addition to the organic EL display device and the liquid crystal display device, a quantum dot display device using a quantum dot panel as a display panel may be used. The quantum dot panel utilizes a quantum dot layer made of quantum dots as a light emitting layer like the organic EL layer. The quantum dot layer is desirably constituted by, for example, a blue quantum dot emitting a blue color ray, a green quantum dot emitting a green color ray and a red quantum dot emitting a red color ray.

(20) The above-mentioned embodiments have exemplified a case in which as a coating method of the first conductive layer and the second conductive layer, a dispenser is used; however, in addition to this, for example, a screen printing method may be used.

(21) As in the case of the above-mentioned (11) and (12), when the materials for the first regulating portion, the second regulating portion, the first in-print layer and the second in-print layer are respectively made different from an ultraviolet ray curable resin material, the viscosity of a material for the first regulating portion and the second regulating portion is desirably made higher than the viscosity of a material for the first in-print layer and the second in-print layer. With this arrangement, the flowability of the material for the first in-print layer and the second in-print layer having a relatively low viscosity can be regulated by the first regulating portion and the second regulating portion having a relatively high viscosity. Moreover, in the first regulating portion forming step and the second regulating portion forming step, it is possible to omit work for making the first regulating portion and the second regulating portion semi-cured.

1. A substrate comprising:
an in-print layer including a conductive layer formation groove formed by partially recessing a surface;
a conductive layer formed inside the conductive layer formation groove; and
a regulating portion disposed contact an end portion of the in-print layer to regulate a formation range of the in-print layer.

2. The substrate according to claim 1, wherein
the in-print layer has a substantially square shape, and
the regulating portion is disposed to contact each of end portions on three sides of the in-print layer.

3. The substrate according to claim 1 further comprising:
a second in-print layer disposed to be overlapped with a formation surface of the conductive layer formation groove on the in-print layer, and has a second conductive layer formation groove formed by partially recessing the surface;
a second conductive layer formed inside the second conductive layer formation groove; and
a second regulating portion disposed to contact an end portion of the second in-print layer to regulate a formation range of the second in-print layer.

4. The substrate according to claim 3 further comprising a terminal composed of one portion of the conductive layer and disposed on an end portion of the in-print layer,
wherein the second in-print layer is disposed so as not to be overlapped with the terminal; and
the second regulating portion is disposed at least between the second in-print layer and the terminal.

5. The substrate according to claim 3, wherein the conductive layer and the second conductive layer at least portions of which form an electrostatic capacitance relative to a position input body for carrying out a positional input so that an input position is detectable by the position input body, respectively constitute a first position detection electrode and a second position detection electrode that are not overlapped with each other.

6. The substrate according to claim 3, wherein the conductive layer and the second conductive layer at least portions of which form a ground wiring and a second ground wiring that are ground connected with each other are installed and a conductive paste that is disposed so as to straddle between the in-print layer and the second in-print layer and connected to the ground wiring and the second ground wiring is installed.

7. The substrate according to claim 6, wherein the second in-print layer is disposed so as not to be overlapped with the ground wiring and the second regulating portion is disposed at least between the second in-print layer and the ground wiring.

8. A display device comprising:
the substrate according to claim 1; and
a display panel having a surface on which the substrate is installed.

9. The display device according to claim 8, wherein a panel terminal is installed on an end portion of the display panel and the regulating portion is disposed at least between the in-print layer and the panel terminal.

10. The display device according to claim 8, wherein the in-print layer is made of an ultraviolet ray curable resin material.

11. The display device according to claim 10, wherein the display panel is made of a synthetic resin so as to have flexibility.

12. A method of producing a substrate comprising the steps of:
forming an in-print layer;
forming a conductive layer formation groove by partially recessing the surface of the in-print layer;
forming a conductive layer inside the conductive layer formation groove; and
prior to the in-print layer forming step, forming a regulating portion so as to be made in contact with an end portion of the in-print layer.

13. The method of producing the substrate according to claim 12, wherein in the regulating portion forming step, the regulating portion made of a curable material is semi-cured.

14. The method of producing the substrate according to claim 13, wherein in the regulating portion forming step, the regulating portion has a thickness larger than the thickness of the in-print layer, and in the in-print layer forming step, a curable material is used for a material for the in-print layer, and the curable material is compressed and deformed together with the regulating portion in a semi-cured state.

15. The method of producing a substrate according to claim 12, wherein the regulating portion is drawn and formed by using a dispenser in the regulating portion forming step.
